(19) United States
(12) Patent Application Publication
(10) Pub. No.: US 2018/0358989 A1
(43) Pub. Date: Dec. 13, 2018

(54) Non-volatile Storage Systems With Application-Aware Error-Correcting Codes

(71) Applicant: Western Digital Technologies, Inc., San Jose, CA (US)

(72) Inventors: Pankaj Mehra, San Jose, CA (US); Xinmiao Zhang, Seattle, WA (US)

(73) Assignee: Western Digital Technologies, Inc., San Jose, CA (US)

(21) Appl. No.: 15/696,787

(22) Filed: Sep. 6, 2017

Related U.S. Application Data
(60) Provisional application No. 62/517,461, filed on Jun. 9, 2017.

(51) Int. Cl. H03M 13/00; G06F 11/10; G11C 29/52

(52) U.S. Cl. CPC H03M 13/6505; G11C 29/52; G06F 11/1068

(57) ABSTRACT

A memory system (e.g., a solid state drive, or SSD) uses application-aware ECC schemes to make use of the specifics of a database schema and analytic queries. Only the fields relevant to the query are decoded, other fields are largely ignored. Integrated interleaved (II) codes and product codes approaches are described. Compared to traditional ECC schemes that decode the entire records before any fields to be used by the analytics are available, the new application-aware ECC schemes may achieve orders of magnitudes throughput improvement and/or substantially lower decoder complexity.

This application claims the benefit of U.S. Provisional Application 62/517,461 “Non-Volatile Storage System with Application-Aware Error-Correcting Codes”, filed on Jun. 9, 2017.

### BACKGROUND

Non-volatile semiconductor memory is used in solid state drives (SSD). As Internet-scale services continue to grow, real time data processing and data analytics by ad-hoc queries on large volumes of data is emerging as a critical application. Additionally, as memory density continues to scale, SSD capacities continue to scale exponentially. Current enterprise systems are ill-equipped to manage these trends as they rely on moving huge volumes of data out into a system's main memory for processing. These solutions rely on storing data at one location (i.e. a storage device like an SSD) and move data to a different location (typically DRAM) for computation. While this method works for some applications with limited data sizes, applications with large scale data cannot use this method because of the time wasted on transferring data and the prohibitively high cost and power consumption of including large scale (e.g. petabyte) DRAM capacity in such systems.

One use of SSDs or other memory systems is for the storage of databases. A record in a database may consist of multiple fields. A query may test certain fields and select the records satisfying specified conditions. Also, the query may retrieve only some of the fields in the selected records. To protect the integrity of data stored in a memory system, the data is often protected by error correcting codes (ECCs). Typically, one or multiple records are included in an ECC codeword. In traditional ECC schemes, such as LDPC or BCH codes, all bits in the codeword need to be decoded before any decoded bits are generated. Hence, even if a query to a database only involves a few fields, the entire record needs to be decoded. Decoding complexity and power are wasted over those irrelevant fields, preventing very high throughput from being achieved.

### BRIEF DESCRIPTION OF THE DRAWINGS

Like-numbered elements refer to common components in the different figures.

FIG. 1 is a block diagram of one embodiment of a solid state drive that comprises a Controller, non-volatile memory for storing data and a compute engine near the location of the data that can be used to perform common data manipulation operations.

FIG. 2 is a block diagram of one embodiment of a solid state drive that comprises a Controller, non-volatile memory for storing data and a compute engine near the location of the data that can be used to perform common data manipulation operations.

FIG. 3 is a block diagram of one embodiment of a Front End Processor Circuit with a compute engine. The Front End Processor Circuit is part of a Controller.

FIG. 4 is a block diagram of one embodiment of a Back End Processor Circuit. In some embodiments, the Back End Processor Circuit is part of a Controller.

FIG. 5 is a block diagram of one embodiment of a memory package.

FIG. 6 is a block diagram of one embodiment of a memory die.

FIG. 7 is a block diagram of one embodiment of a solid state drive that comprises a Controller, non-volatile memory for storing data and a compute engine near the location of the data that can be used to perform common data manipulation operations.

FIG. 8 is a block diagram of one embodiment of a solid state drive that comprises a Controller, non-volatile memory for storing data and a compute engine near the location of the data that can be used to perform common data manipulation operations.

FIG. 9 is a block diagram of one embodiment of a Front End Processor Circuit without a compute engine. In some embodiments, the Front End Processor Circuit is part of a Controller.

FIG. 10 is a block diagram of one embodiment of a solid state drive that comprises a Controller, non-volatile memory for storing data and a compute engine near the location of the data that can be used to perform common data manipulation operations.

FIG. 11 is a block diagram of one embodiment of a Back End Processor Circuit with a compute engine. In some embodiments, the Back End Processor Circuit is part of a Controller.

FIG. 12 is a block diagram of one embodiment of a solid state drive that comprises a Controller, non-volatile memory for storing data and a compute engine near the location of the data that can be used to perform common data manipulation operations.

FIG. 13A is a block diagram of one embodiment of a solid state drive that comprises a Controller, non-volatile memory for storing data and a compute engine near the location of the data that can be used to perform common data manipulation operations.

FIG. 13B is a block diagram of one embodiment of a solid state drive that comprises a Controller, non-volatile memory for storing data and a compute engine near the location of the data that can be used to perform common data manipulation operations.

FIG. 14 is a block diagram of one embodiment of a memory package with a compute engine.

FIG. 15 is a block diagram of one embodiment of a solid state drive that comprises a Controller, non-volatile memory for storing data and a compute engine near the location of the data that can be used to perform common data manipulation operations.

FIG. 16 is a block diagram of one embodiment of a memory die with a compute engine.

FIG. 17 is a block diagram of one embodiment of a solid state drive that comprises a Controller, non-volatile memory for storing data and a compute engine near the location of the data that can be used to perform common data manipulation operations.

FIG. 18 is a block diagram of one embodiment of a memory die with circuitry under the memory array.

FIG. 19 is a block diagram of one embodiment of a memory die with circuitry under the memory array.

FIG. 20 is a block diagram to illustrate some of the elements involved in embodiments for the implementation of application aware error correcting codes.

FIG. 21 illustrates the structure of an example Integrated Interleaved (II) ECC code.

FIG. 22 is a flowchart describing one embodiment of writing user data that is encoded using an integrated interleaved code into a memory die.

FIG. 23 illustrates an example of application-aware Integrated Interleaved (II) decoding for a row-oriented database.

FIG. 24 is a flowchart describing one embodiment of reading user data that is encoded using an integrated interleaved code from a memory die.

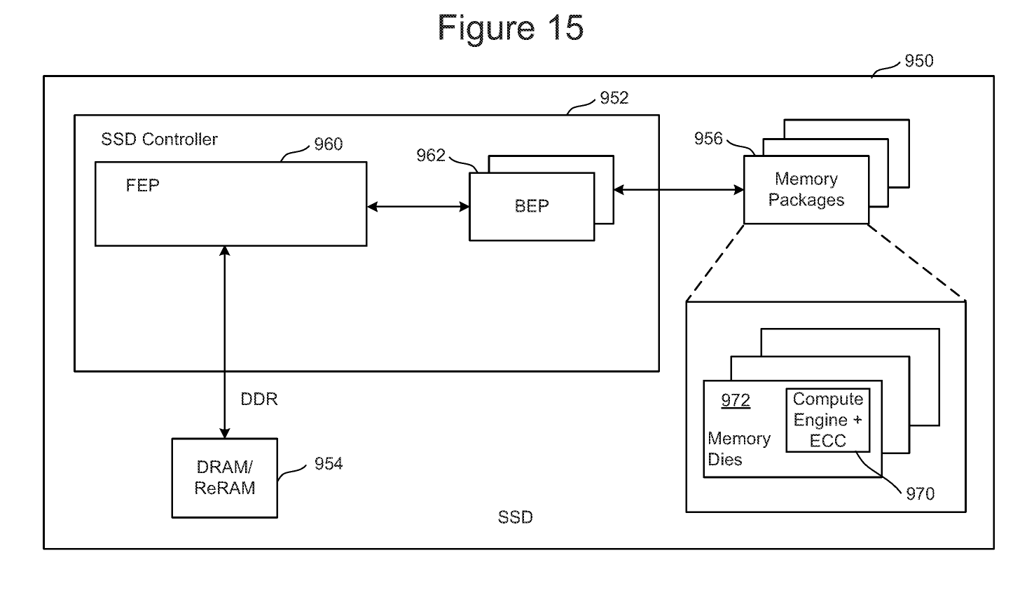

FIG. 15 illustrates an example of application-aware Integrated Interleaved (II) decoding for a column-oriented database.

FIG. 26 illustrates the structure of product codes using both a column code and a row code.

FIG. 27 is a flowchart describing one embodiment of writing user data that is encoded using a product code structure into a memory die.

FIG. 28 illustrates examples of application-aware product code decoding for row-oriented database.

FIG. 29 is a flowchart describing one embodiment of reading user data that is encoded using a product code structure from a memory die.

FIG. 30 illustrates examples of application-aware product code decoding for column-oriented database.

### DETAILED DESCRIPTION

To increase the rate of data throughput for data analytics, a data-centric model is presented that allocates computing resource close to the storage elements of a non-volatile memory system. The data is processed, analyzed, or both, next or close to the storage elements, and the results are sent through the limited bandwidth I/O path to the host. Such in or near storage computing not only bridges the discrepancy between the very high throughput required by big data analytics and the limited storage device I/O bandwidth, but also substantially reduces the energy needed for moving the data across the storage stack.

Error-correcting codes (ECCs) are used to help ensure data integrity. Data read from NAND or other storage media pass through error-correcting decoders so that possible errors are corrected before they are involved in any computation and analytics. To match the high-speed achievable with in or near storage data processing, the error correction engines may run at high throughput rates (e.g., 10 GB/s or higher). Such a high throughput is very difficult to achieve by traditional ECC schemes, even if possible advancements of integrated circuit technology are considered.

The following presents ECC schemes that take advantage of the specifics of the analytic queries, and decode only the relevant fields and selected records while ignoring the others. In the case that a small percentage of the records are selected and/or a few fields are involved, which happens in most big data analytic queries, such query-aware ECC schemes can bring orders of magnitudes of improvements on decoding throughput and complexity.

The application-aware ECC scheme exploits the knowledge about the database schema and data queries, and decodes only the fields relevant to the query as much as practical. Specifically, depending on the embodiment, the following information may be available to the ECC decoder:
1. The logical and physical database schema, including the size of database rows, number of columns or fields and their sizes, and whether the layout is row-oriented or column-oriented.
2. The decoder is informed on a query-by-query basis about the set of fields (or columns of records) that will be:
   Used in test conditions (such as in the SELECT . . . WHERE expressions) by the query;
   Projected for retrieval from the SELECTed rows according to the query; and/or
   Don't cares (logical, numerical, branch and bound)
3. The ECC algorithm may optionally be aware of a specified order in which to perform the queries used to search the database (a test evaluation order), such as “condition on column A will be tested before condition on column B”.

Two ECC schemes are described to decode only the fields relevant to the query, while ignoring the other fields. They are integrated interleaved (II) codes and product codes. Compared to traditional ECC schemes that decode the entire records before any fields to be used by the analytics are available, the application-aware ECC schemes may achieve orders of magnitudes throughput improvement and/or substantially lower decoder complexity.

Before considering ECC and error correction engines further, the following examines some of the various options for integrating error correction engines within memory systems and, more specifically, within SSDs. In the embodiments considered below, a memory package can refer to a package that contains NAND dies, ReRAM dies, other non-volatile technologies or some combination of these. The term memory package can also refer to managed memory—i.e. a memory package that contains memory dies with an embedded error correction code (“ECC”) engine/controller to correct errors detected during read operations to the memory.

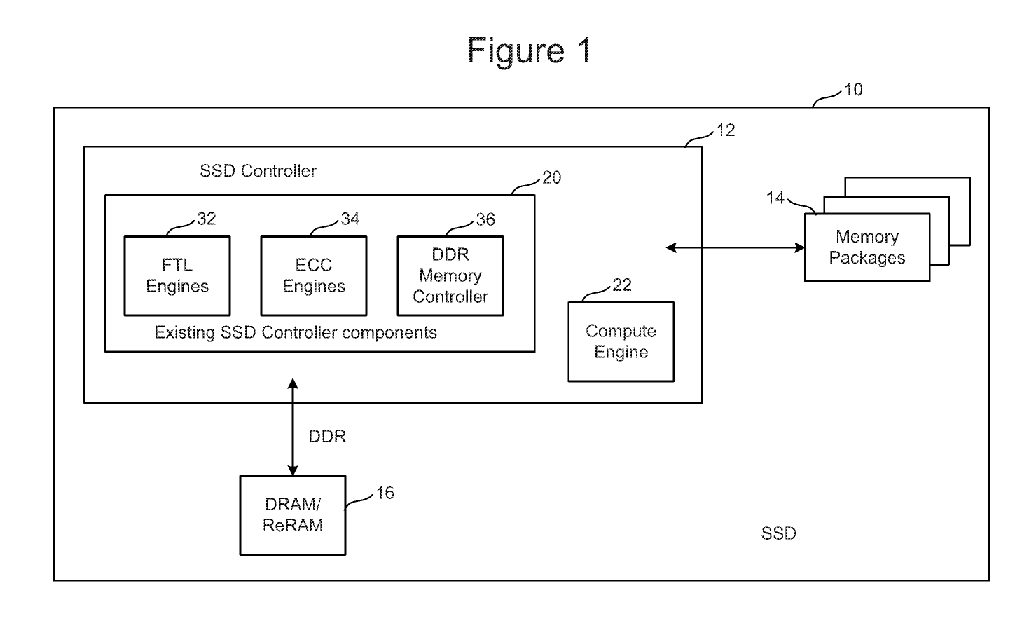

FIG. 1 is a block diagram of one embodiment of SSD 10 that comprises a Controller (SSD Controller) 12, non-volatile memory packages 14 for storing data, DRAM/ReRAM 16, and a compute engine 22 near the location of the data that can be used to perform common data manipulation operations. FIG. 1 presents a high-level design where the compute engine 22 is integrated within the SSD Controller 12. The compute engine 22 can be, for instance, an ASIC that is part of the SSD Controller system on a chip (“SoC”) or can be integrated (deeper) as a hardware circuit within the SSD controller. FIG. 1 shows the SSD Controller 12, a SoC, including existing SSD Controller components that comprise FTL engines 32, error correction (ECC) engines 34, and DDR memory controller 36 for controlling DRAM/ReRAM 16. Included within that SSD Controller 12 is the new proposed compute engine 22 that can be used to perform compute operations on data stored in the non-volatile memory of the memory packages. Examples of the compute operations include scanning the data, searching, filtering, sorting, aggregating data, joining data together, as well as other functions on the data. FIG. 1 shows the SSD Controller 12 in communication with DRAM/ReRAM 16 and in communication with the set of one or more memory packages 14. In one embodiment, the SSD Controller 12 communicates with the memory packages (and/or memory die) using a Toggle Mode interface, which is an asynchronous interface that is able to communicate 32 GB/s. An alternative embodiment could use ONFI interface (Open NAND Flash Interface), which is synchronous and makes use of a clock.

The memory packages include one or more memory die. In one embodiment, each memory die will include its own chip enable that can be controlled by SSD Controller 12. In other embodiments, multiple memory die may share a chip enable, requiring SSD Controller 12 to use addressing to select between the memory die that share a chip enable. In one embodiment, the memory die in the memory packages 14 utilize NAND flash memory. In other embodiments, the memory package can include cross point ReRAM non-volatile memory, which is discussed below.

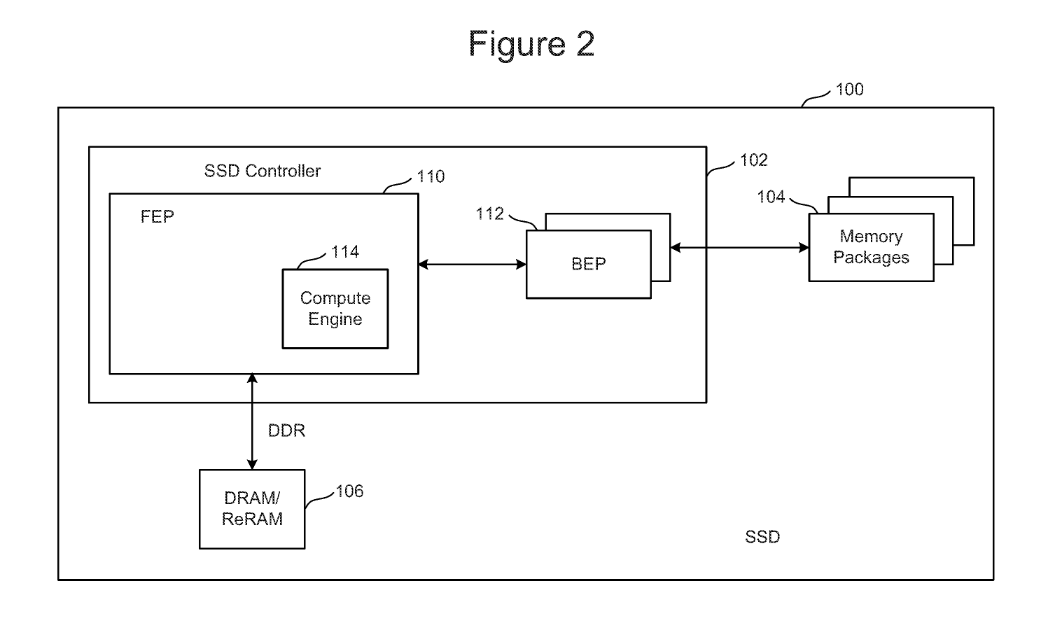

FIG. 2 is a block diagram of one embodiment of a solid state drive 100 that comprises a controller 102, non-volatile memory 104 for storing data, DRAM/ReRAM 106 and a compute engine 114 near the location of the data that can be used to perform common data manipulation operations. The embodiment of FIG. 2 includes an SSD controller 102 comprising a Front End Processor Circuit (FEP) 110 and one or more Back End Processor Circuits (BEP) 112. In one embodiment the FEP110 circuit is implemented on an ASIC. In one embodiment, each BEP circuit 112 is implemented on a separate ASIC. The ASICs for each of the BEP circuits 112 and the FEP circuit 110 are implemented on the same semiconductor such that the SSD controller 102 is manufactured as a SoC. FEP 110 and BEP 112 both include their own processors. In one embodiment, FEP110 and BEP 112 work as a master slave configuration where the FEP110 is the master and each BEP 112 is a slave. For example, FEP circuit 110 implements a flash translation layer, including performing memory management (e.g., garbage collection, wear leveling, etc.), logical to physical address translation, communication with the host, management of DRAM (local volatile memory) and management the overall operation of the SSD (or other non-volatile storage system). The BEP circuit 112 manages memory operations in the memory packages/die at the request of FEP circuit110. For example, the BEP circuit 112 can carry out the read, erase and programming processes. Additionally, the BEP circuit 112 can perform buffer management, set specific voltage levels required by the FEP circuit110, perform error correction (ECC), control the Toggle Mode interfaces to the memory packages, etc. In one embodiment, each BEP circuit 112 is responsible for its own set of memory packages. FIG. 2 shows the FEP circuit 110 in communication with each of the BEP circuits 112 at a bandwidth of 4 GB/s. In the implementation of FIG. 2, the compute engine 114 is designed in as a hardware circuit within FEP110. The compute engine can access high speed, high-bandwidth memory using the DDR interface to access the DRAM 106. In this implementation, the bandwidth available to the compute engine is limited by the bandwidth that connects the FEP110 to the BEP 112.

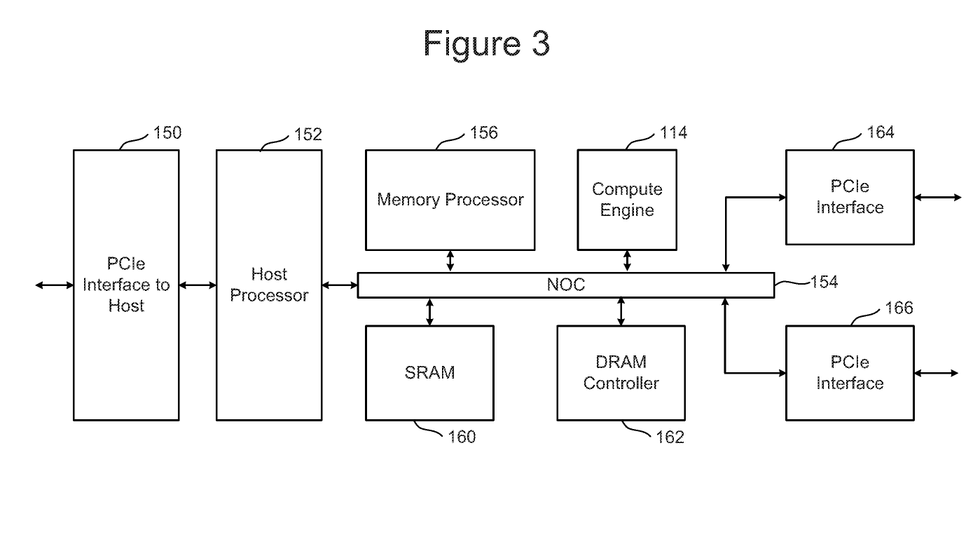

FIG. 3 is a block diagram of one embodiment of an FEP circuit with the compute engine 114 designed into the circuit. The FEP circuit of FIG. 3 is one example implementation of FEP circuit110 of FIG. 2. FIG. 3 shows a PCIe interface 150 to communicate with the host and a host processor 152 in communication with that PCIe interface. The host processor 152 can be any type of processes known in the art that is suitable for the implementation. The host processor 152 is in communication with a network-on-chip (NOC) 154. An NOC is a communication subsystem on an integrated circuit, typically between cores in a SoC. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of SoCs and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, an NOC provides enhanced performance (such as throughput) and scalability in comparison with previous communication architectures (e.g., dedicated point-to-point signal wires, shared buses, or segmented buses with bridges). Connected to and in communication with NOC 154 is the memory processor 156, the compute engine 114, SRAM 160 and a DRAM controller 162. The DRAM controller 162 is used to operate and communicate with the DRAM (e.g., DRAM 106). SRAM 160 is local RAM memory used by the compute engine 114 or the memory processor 156. The memory processor 156 is used to run the FEP circuit and perform the various memory operations. Also in communication with the NOC are two PCIe Interfaces 164 and 166. In the embodiment of FIG. 3, the SSD controller will include two BEP circuits; therefore there are two PCIe Interfaces 164/166. Each PCIe Interface communicates with one of the BEP circuits. In other embodiments, there can be more or less than two BEP circuits; therefore, there can be more than two PCIe Interfaces. In these arrangements, the compute engine 114 is positioned (from the perspective of the host) behind the interface 150 to the host (e.g., on the memory system side of the interface to the host) and behind the API exposed by the Controller (e.g., exposed by the FEP circuit).

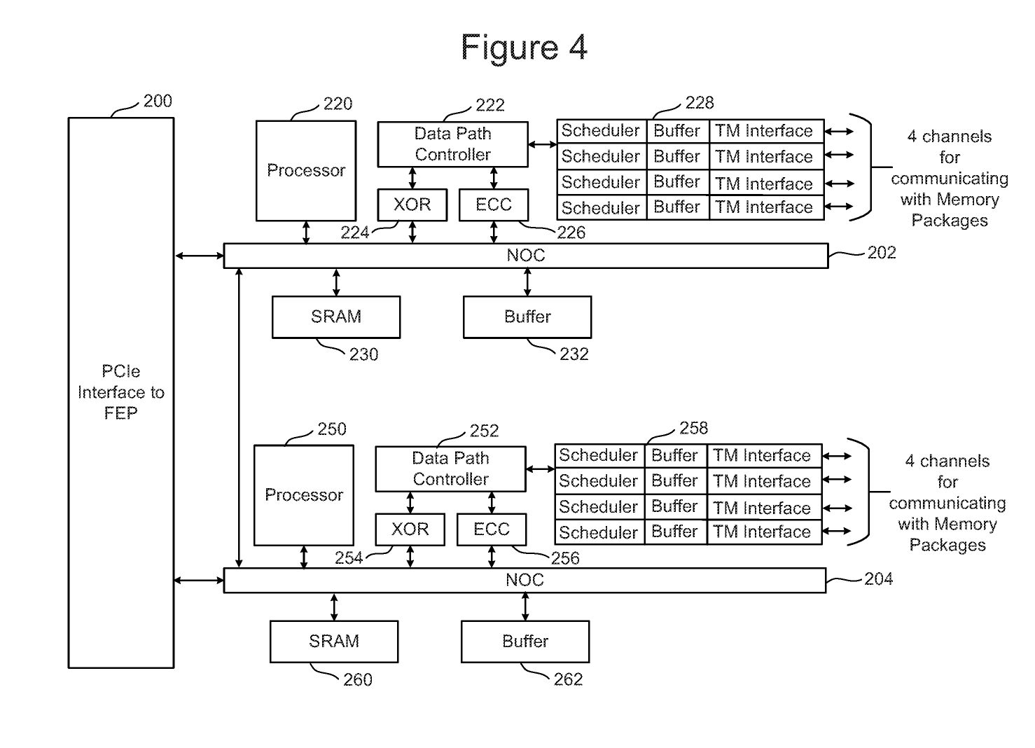

FIG. 4 is a block diagram of one embodiment of the BEP circuit. The BEP circuit of FIG. 4 is one example implementation of BEP circuit 112 of FIG. 2. FIG. 4 shows a PCIe Interface 200 for communicating with the FEP circuit (e.g., communicating with one of PCIe Interfaces 164 and 166 of FIG. 3). PCIe Interface 200 is in communication with two NOCs 202 and 204. In one embodiment, the two NOCs can be combined to one large NOC. Each NOC (202/204) is connected to SRAM (230/260), a buffer (232/262), processor (220/250), and a data path controller (222/252) via an XOR engine (224/254) and an error correction ECC engine (226/256). The ECC engines 226/256 are used to perform error correction, as known in the art. The XOR engines 224/254 are used to XOR the data so that data can be combined and stored in a manner that can be recovered in case there is a programming error. The data path controller is connected to an interface module for communicating via four channels with memory packages. Thus, the top NOC 202 is associated with an interface 228 for four channels for communicating with memory packages and the bottom NOC 204 is associated with an interface 258 for four additional channels for communicating with memory packages. Each interface 228/258 includes four Toggle Mode interfaces (TM Interface), four buffers and four schedulers. There is one scheduler, buffer and TM Interface for each of the channels. The processor can be any standard processor known in the art. The data path controllers 222/252 can be a processor, FPGA, microprocessor or other type of controller. The XOR engines 224/254 and ECC engines 226/256 are dedicated hardware circuits, known as hardware accelerators. In other embodiments, the XOR engines 224/254 and ECC engines 226/256 can be implemented in software. The scheduler, buffer, and TM Interfaces are hardware circuits.

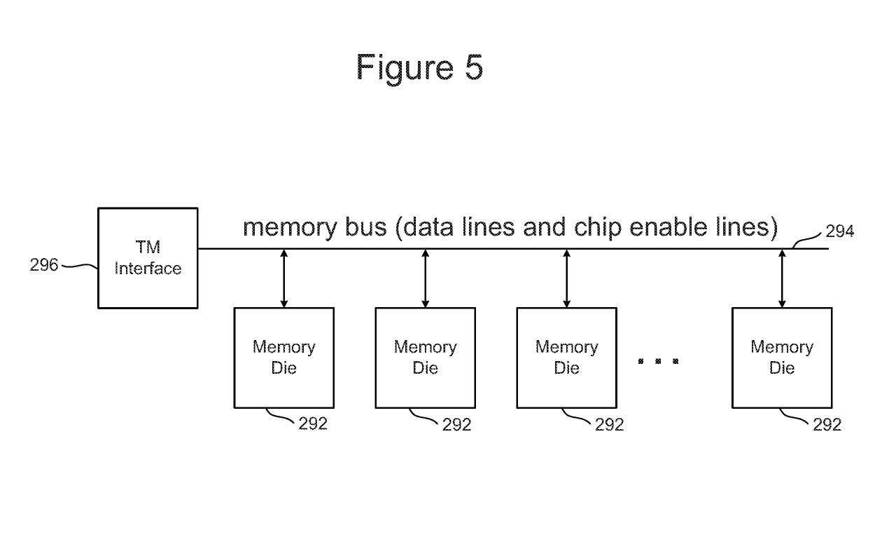

FIG. 5 is a block diagram of one embodiment of a memory package. For example, the memory package of FIG. 5 is an example implementation of a memory package included in memory packages 14 of FIG. 1 or memory packages 104 of FIG. 2. FIG. 5 shows a plurality of memory die 292 connected to a memory bus (data lines and chip enable lines) 294. The memory bus 294 connects to a Toggle Mode Interface 296 for communicating with the TM Interface of an BEP circuit (see e.g. FIG. 4). In some embodiments, the memory package can include a small controller connected to the memory bus and the TM Interface. The memory package can have one or more memory die. In one embodiment, each memory package includes eight or 16 memory die; however, other numbers of memory die can also be implemented. The technology described herein is not limited to any particular number of memory die.

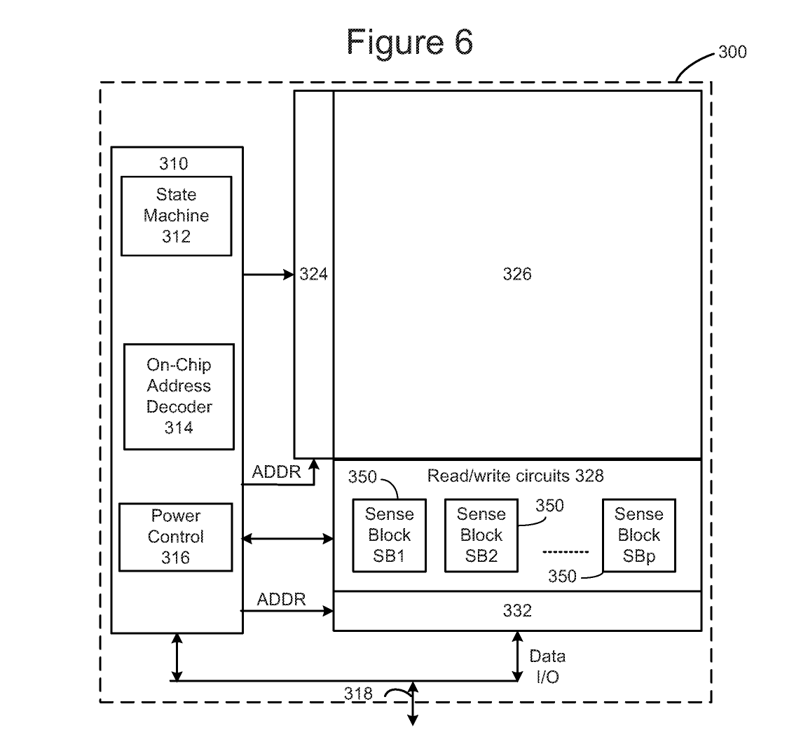

FIG. 6 is a functional block diagram of one embodiment of a memory die 300. Note that memory is one example implementation of memory die 292 of FIG. 5. The components depicted in FIG. 6 are electrical circuits. Memory die 300 includes a three dimensional memory structure 326 of memory cells (such as, for example, a 3D array of memory cells), control circuitry 310, and read/write circuits 328. In other embodiments, a two dimensional array of memory cells can be used. Memory structure 326 is addressable by word lines via a row decoder 324 and by bit lines via a column decoder 332. The read/write circuits 328 include multiple sense blocks 350 including SB1, SB2, . . . , SBp (sensing circuitry) and allow a page of memory cells to be read or programmed in parallel. Commands and data are transferred between to/from memory die 300 via lines 318. In one embodiment, memory die 300 includes a set of input and/or output (I/O) pins that connect to lines 318.

Memory structure 326 may comprise one or more arrays of memory cells including a 3D array. The memory structure may comprise a monolithic three dimensional memory structure in which multiple memory levels are formed above (and not in) a single substrate, such as a wafer, with no intervening substrates. The memory structure may comprise any type of non-volatile memory that is monolithically formed in one or more physical levels of arrays of memory cells having an active area disposed above a silicon substrate. The memory structure may be in a non-volatile memory device having circuitry associated with the operation of the memory cells, whether the associated circuitry is above or within the substrate.

Control circuitry 310 cooperates with the read/write circuits 328 to perform memory operations (e.g., erase, program, read, and others) on memory structure 326, and includes a state machine 312, an on-chip address decoder 314 and a power control module 316. In one embodiment, state machine 312 is programmable by software. In other embodiments, state machine 312 does not use software and is completely implemented in hardware (e.g., electrical circuits). In one embodiment, control circuitry 310 includes registers, ROM fuses and other storage devices for storing default values such as base voltages and other parameters.

The on-chip address decoder 314 provides an address interface between addresses used by a host or controller to the hardware address used by the decoders 324 and 332. Power control module 316 controls the power and voltages supplied to the word lines and bit lines during memory operations. It can include drivers for word line layers (discussed below) in a 3D configuration, select transistors (e.g., SGS and SGD transistors, described below) and source lines. Power control module 316 may include charge pumps for creating voltages. The sense blocks include bit line drivers.

Multiple memory elements in memory structure 326 may be configured so that they are connected in series or so that each element is individually accessible. By way of non-limiting example, flash memory devices in a NAND configuration (NAND flash memory) typically contain memory elements connected in series. A NAND string is an example of a set of series-connected memory cells and select gate transistors that can be used to implement memory structure 326 as a three-dimensional memory structure.

A NAND flash memory array may be configured so that the array is composed of multiple NAND strings of which a NAND string is composed of multiple memory cells sharing a single bit line and accessed as a group. Alternatively, memory elements may be configured so that each element is individually accessible, e.g., a NOR memory array. NAND and NOR memory configurations are exemplary, and memory cells may be otherwise configured.

The memory cells may be arranged in the single memory device in an ordered array, such as in a plurality of rows and/or columns. However, the memory elements may be arrayed in non-regular or non-orthogonal configurations, or in structures not considered arrays.

A three dimensional memory array is arranged so that memory cells occupy multiple planes or multiple memory device levels, thereby forming a structure in three dimensions (i.e., in the x, y and z directions, where the z direction is substantially perpendicular and the x and y directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in they direction) with each column having multiple memory cells. The vertical columns may be arranged in a two dimensional configuration, e.g., in an x-y plane, resulting in a three dimensional arrangement of memory cells, with memory cells on multiple vertically stacked memory planes. Other configurations of memory elements in three dimensions can also constitute a three dimensional memory array.

By way of non-limiting example, in a three dimensional NAND memory array, the memory elements may be coupled together to form vertical NAND strings with charge-trapping material that traverse across multiple horizontal memory device levels. One example of a three dimensional NAND memory array that can be used to implement memory structure 326 can be found in U.S. Pat. No. 9,343,156, incorporated herein by reference in its entirety.

Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

A person of ordinary skill in the art will recognize that the technology described herein is not limited to a single specific memory structure, but covers many relevant memory structures within the spirit and scope of the technology as described herein and as understood by one of ordinary skill in the art.

Although an example memory system is a three dimensional memory structure that includes vertical NAND strings with charge-trapping material, other (2D and 3D) memory structures can also be used with the technology described herein. For example, floating gate memories (e.g., NAND-type and NOR-type flash memory), ReRAM memories, magnetoresistive memory (e.g., MRAM), and phase change memory (e.g., PCRAM) can also be used.

One example of a ReRAM memory includes reversible resistance-switching elements arranged in cross point arrays accessed by X lines and Y lines (e.g., word lines and bit lines). One example of a three dimensional memory array that can be used to implement memory structure 326 can be found in U.S. Patent Application 2016/0133836, “High Endurance Non-Volatile Storage,” incorporated herein by reference in its entirety.

In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Magnetoresistive memory (MRAM) stores data by magnetic storage elements. The elements are formed from two ferromagnetic plates, each of which can hold a magnetization, separated by a thin insulating layer. One of the two plates is a permanent magnet set to a particular polarity; the other plate's magnetization can be changed to match that of an external field to store memory. This configuration is known as a spin valve and is the simplest structure for an MRAM bit. A memory device is built from a grid of such memory cells. In one embodiment for programming, each memory cell lies between a pair of write lines arranged at right angles to each other, parallel to the cell, one above and one below the cell. When current is passed through them, an induced magnetic field is created.

Phase change memory (PCRAM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. Note that the use of “pulse” in this document does not require a square pulse, but includes a (continuous or non-continuous) vibration or burst of sound, current, voltage light, or other wave.

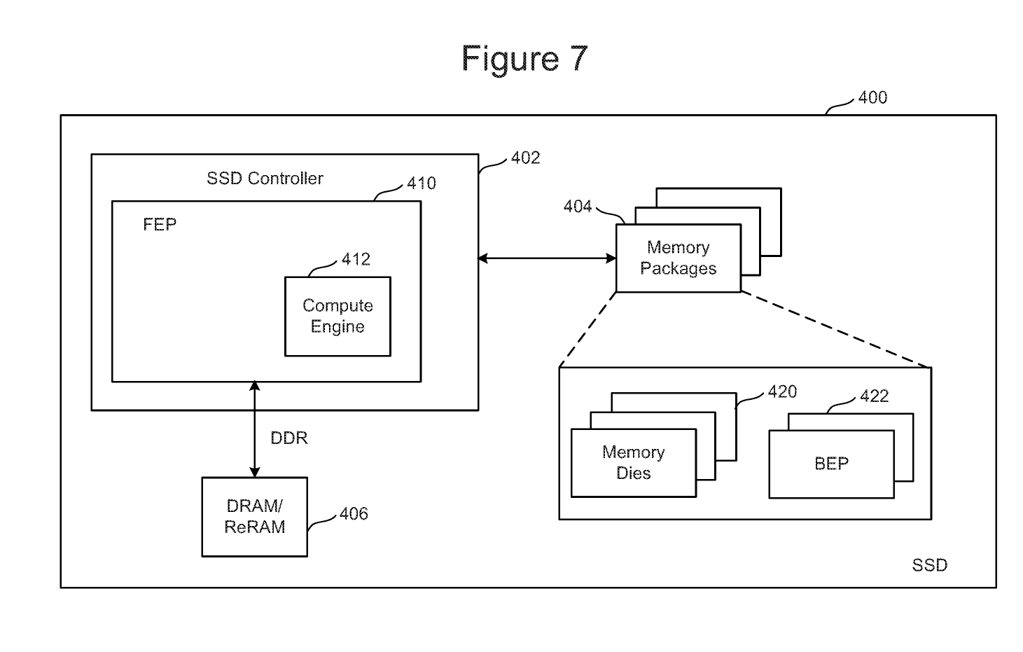

FIG. 7 is a block diagram of one embodiment of a solid state drive 400 that comprises a controller 402, non-volatile memory packages 404 for storing data, DRAM/ReRAM 406, and a compute engine 412 near the location for that data that can be used to perform common data manipulation operations. Controller 402 includes FEP circuit410. In the embodiment of FIG. 7, compute engine 412 is integrated within FEP circuit410 and the one or more BEP circuits 422 are now incorporated within the memory packages 404. In this implementation, the SSD controller contains only one ASIC, for the FEP circuit. That is, the SSD controller 402 is in communication with the memory packages 404, where each memory package includes multiple memory die 420 and one or more BEP circuits 422. One example embodiment of memory die 420 is depicted in FIG. 6. One example of BEP circuit 422 is depicted in FIG. 4. One example of FEP circuit410 with an integrated compute engine 412 is depicted in FIG. 3.

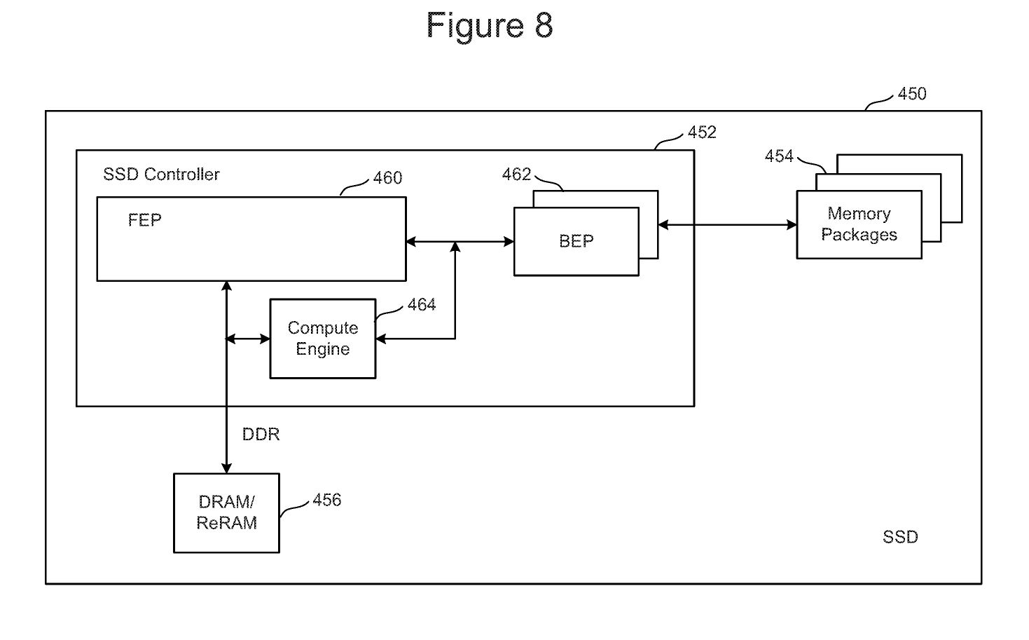

FIG. 8 is a block diagram of one embodiment of a solid state drive 450 that comprises a controller 460, non-volatile memory packages 454 for storing data, DRAM/ReRAM 456, and a compute engine 464 near the location of the data that can be used to perform common data manipulation operations. In the embodiment of FIG. 8 the compute engine 464 is a standalone ASIC (application specific integrated circuit) that is integrated with the SSD controller 460 as a SoC. In this implementation, controller 460 includes a FEP circuit460 in communication with one or more BEP circuits 462. Compute engine 464 is outside of and connected to FEP circuit462, connected to the BEP circuit and connected to the high speed DRAM memory with separate interfaces. The bandwidth available to the compute engine 464 is lower than or equal to the bandwidth of the embodiment of FIG. 2. This implementation is preferred when the development of the FEP circuit 462 and the compute engine 464 needs to be kept separate. One example of BEP circuit 422 is depicted in FIG. 4. One example of memory packages 454 is depicted in FIG. 5.

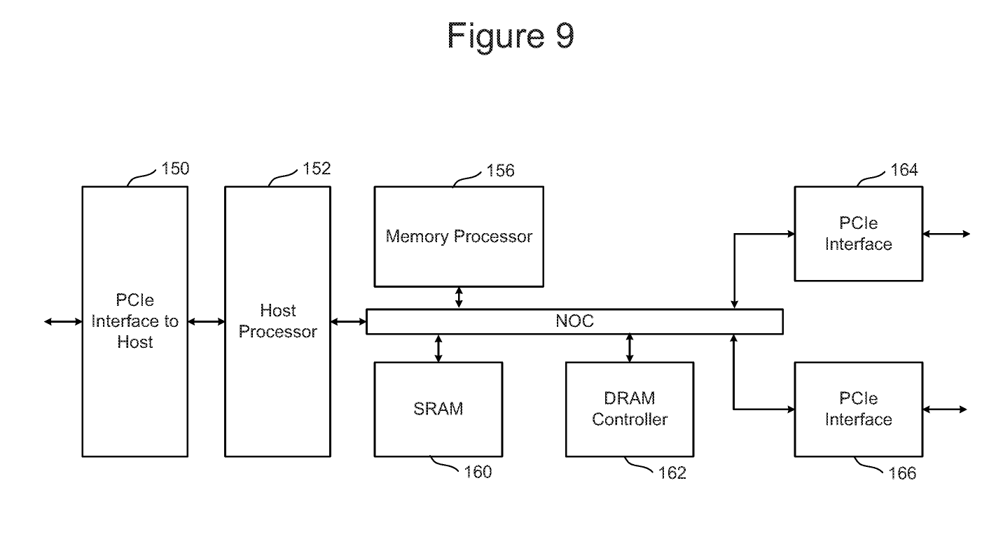

FIG. 9 is a block diagram of one embodiment of a FEP circuit without a compute engine, that is suitable for the embodiment of FIG. 8 (e.g., FEP circuit460). FIG. 9 shows all the components of FIG. 3, but without the compute engine. That is, FIG. 9 depicts PCIe interface 150, host processor 152, NOC 154, memory processor 156, SRAM 160, DRAM controller 162, and PCIe Interfaces 164 and 166. In the embodiment of FIG. 9, the SSD controller will include two BEP circuits; therefore there are two PCIe Interfaces. Each PCIe Interface communicates with one of the BEP circuits. In other embodiments, there can be more or less than two BEP circuits; therefore, there can be more or less than two PCIe Interfaces.

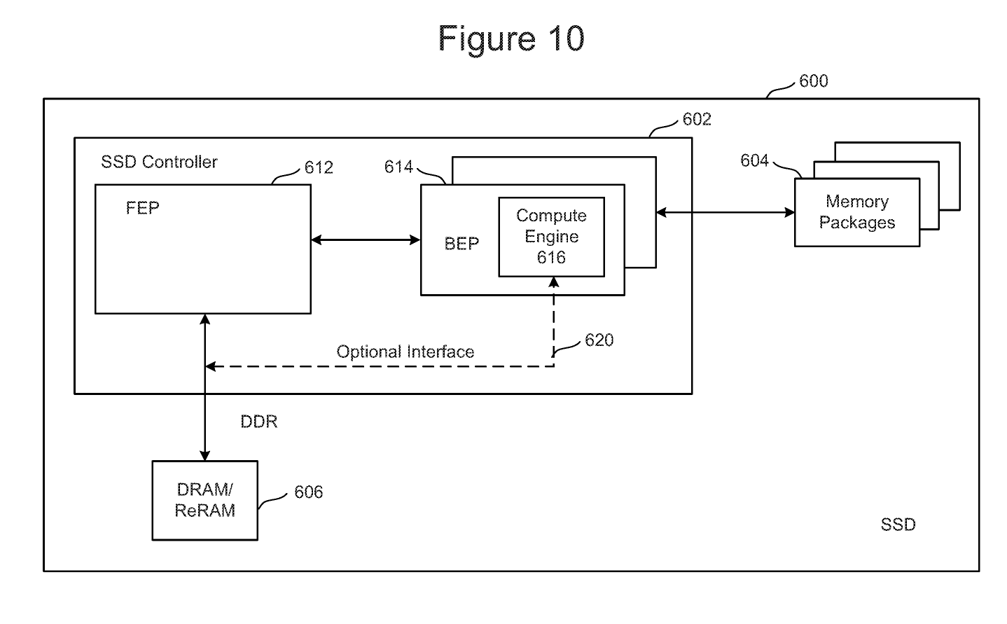

FIG. 10 is a block diagram of one embodiment of a solid state drive 600 that comprises a controller 602, non-volatile memory packages 604 for storing data, DRAM/ReRAM 606, and compute engine 616 near the location of the data that can be used to perform common data manipulation operations. Controller 602 includes a FEP circuit612 connected to one or more BEP circuits 614. In this embodiment a compute engine 616 is integrated with an BEP circuit 614. That is, the compute engine 616 is implemented in the ASIC for the BEP circuit 614. The bandwidth available to the compute engine is now determined by the number of toggle mode channels present in each BEP circuit and the bandwidth of the toggle mode channels. The BEP circuit 614 may also contain an optional interface 620 to connect to the DRAM/ReRAM chip. A direct interface to the high speed memory provides the compute engine 616 with fast access to the memory to store temporary working data. In the absence of a direct interface, temporary working data is streamed via the interface that connects the BEP circuits to the FEP circuit. One example of FEP circuit 612 is depicted in FIG. 9. One example of memory packages 604 is depicted in FIG. 5.

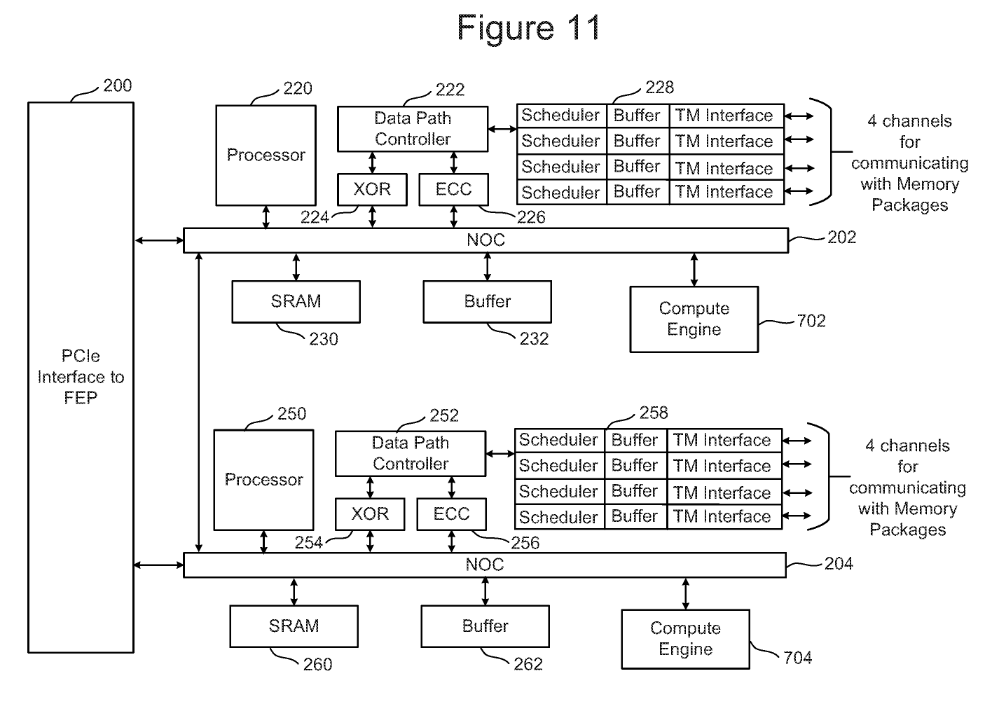

FIG. 11 is a block diagram of one embodiment of an BEP circuit that includes a compute engine. The embodiment of the BEP circuit of FIG. 11 is appropriate for use in the embodiment of FIG. 10 (e.g., as an BEP circuit 614). The components of FIG. 11 are the same as the components of FIG. 4, but further includes a compute engine 702 connected to the top NOC 202 and a second compute engine 704 connected to the bottom NOC 204. In another embodiment, one compute engine can connect to both NOCs. In another embodiment, the two NOCs are connected together and the combined NOC will connect to one, two or multiple compute engines. In the embodiment of FIG. 11, there is one compute engine for each set of four channels. In other embodiments, the channels grouped together can include more or less than four channels.

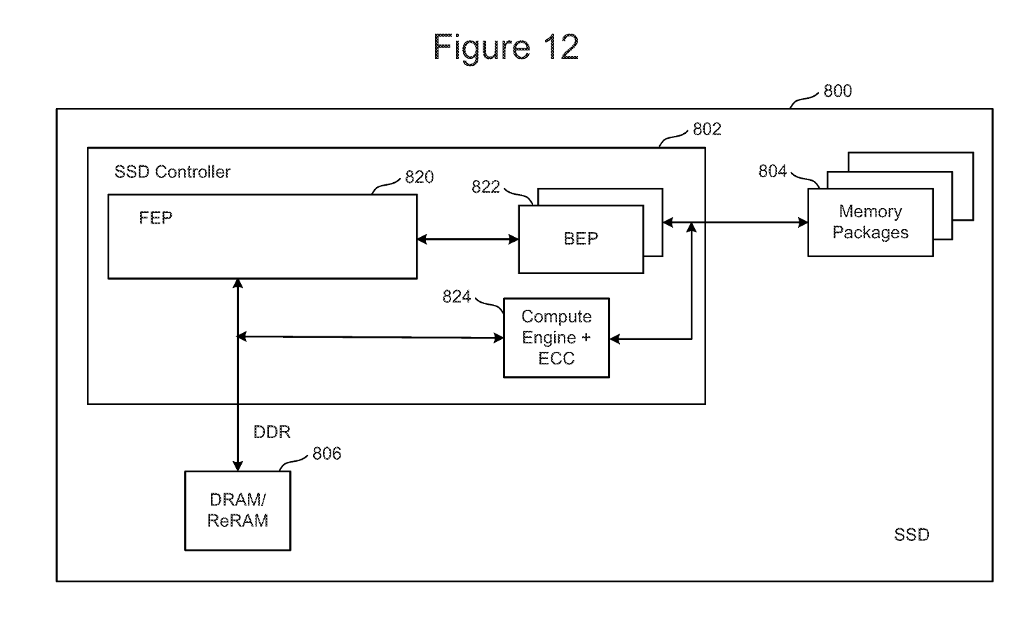

FIG. 12 is a block diagram of one embodiment of a solid state drive 800 that comprises a controller 802, non-volatile memory packages 804 for storing data, DRAM/ReRAM 806 and a compute engine 824 near the location of the data that can be used to perform common data manipulation operations. Controller 802 includes FEP circuit820 connected to one or more BEP circuits 822. In the embodiment of FIG. 12, compute engine 824 is a standalone ASIC that is connected directly to the toggle mode (TM) channels from the BEP circuits. In such implementations, the compute engine should optionally include an error correction engine in order to decode and correct data read from the flash memory (or other type of nonvolatile memory in the memory packages) before being processed by the compute engine. The compute engine 824 can also be connected to the high speed, high-bandwidth DRAM memory 806 through a standard DDR interface to the DRAM/ReRAM chip and to FEP circuit820. One example of FEP circuit 820 is depicted in FIG. 9. One example of memory packages 804 is depicted in FIG. 5. One example of BEP circuit 822 is depicted in FIG. 4.

The table below presents properties of the designs presented so far:

| | Accesses NAND | | | |
|---|---|---|---|---|
| | physically/logically | Encapsulates/ | Integration | Available |
| | (=core relative | bypasses | locus of | NAND/SCM |
| FIG. | to FTL) | ECC | core | bandwidth |
| 2, 7 | L | E | FEP | Low |
| 8 | L | E | FEP-BEP | Low |
| | | | interface | |
| 10 | P | E | BEP | High |
| 12 | P | B | BEP-NAND | High |
| | | | interface | |

The embodiments discussed above show various implementations of integrating the compute engine with the controller. In a different set of implementations, the compute engine can be integrated with the memory package, referred to as memory package level integration.

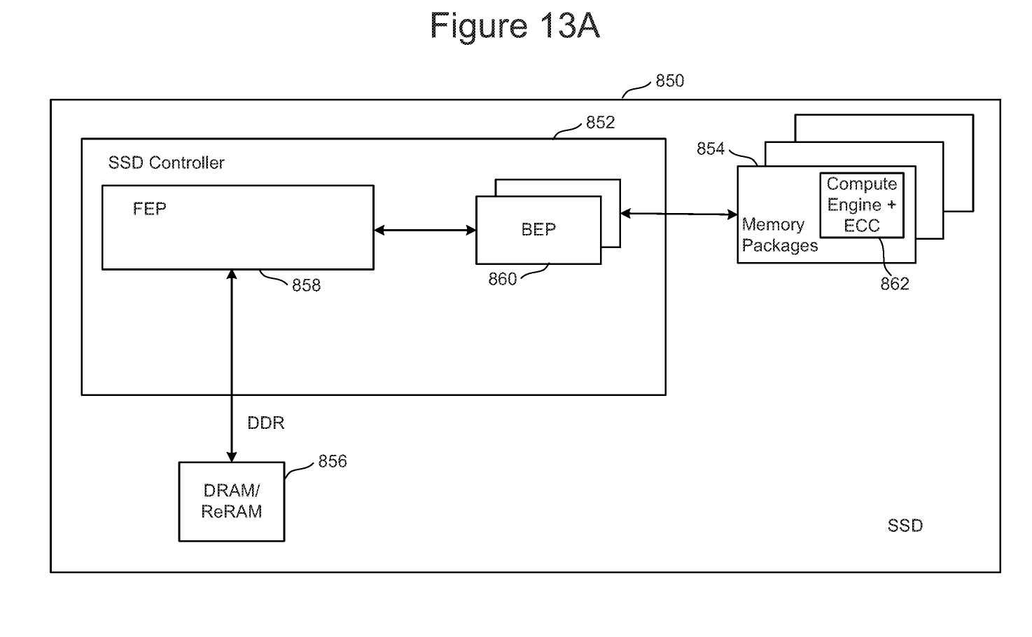

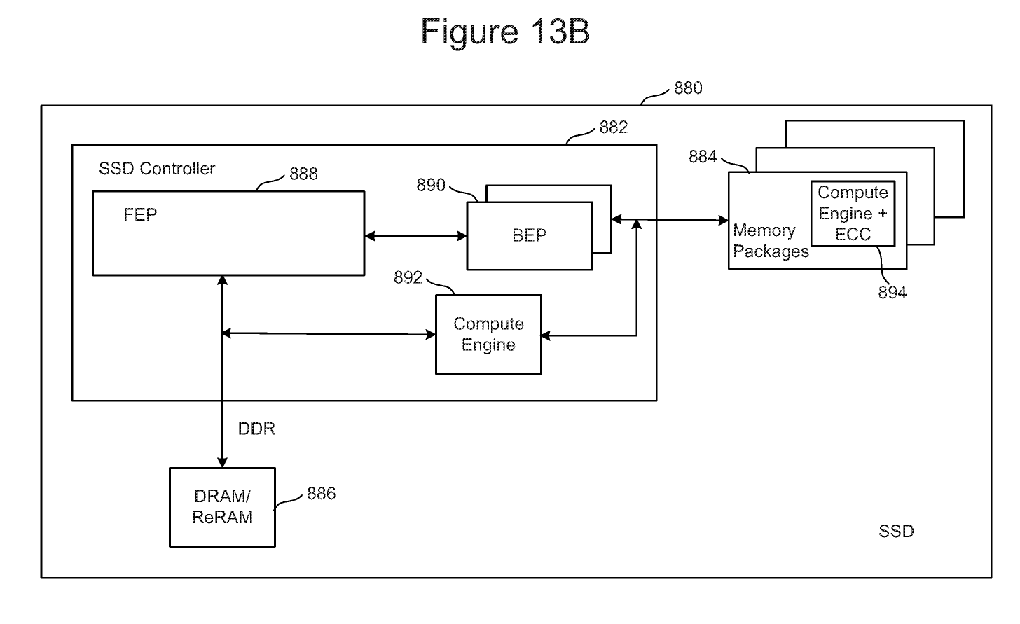

FIG. 13A is a block diagram of one embodiment of a solid state drive 850 that includes memory package level integration, comprising a controller 852, non-volatile memory packages 854 for storing data, DRAM/ReRAM 856 and a compute engine 862 near the location of the data that can be used to perform common data manipulation operations. Controller 852 includes FEP circuit858 connected to one or more BEP circuits 860. The one or more BEP circuits 860 connect to the non-volatile memory packages 854. One example of FEP circuit858 is depicted in FIG. 9. One example of BEP circuit 860 is depicted in FIG. 4. In the embodiment depicted in FIG. 13A, the compute engine is integrated with each memory package. A memory package, which typically includes multiple memory die (e.g., NAND non-volatile memory or other type of non-volatile memory), is now modified to include the compute engine ASIC within the memory package. In one embodiment, the memory package should also include an error correction engine (or at least the decoder portion of the error correction engine) to decode code words read from the memory and to correct the data read from the non-volatile memory die before being processed by the compute engine. Thus, compute engine 862 includes an error correction (ECC) engine. In other embodiments, the compute engine can operate on data that has not been subjected to ECC decoding. The memory package can optionally include high-speed memory like DRAM to support the compute engine with access to temporary working data. As the data management operations are within the memory package, the bandwidth available to the compute engine can be much higher than the toggle mode (TM) bandwidth available outside of the memory package.

FIG. 13B is a block diagram of one embodiment of a solid state drive 880 that includes controller 882, non-volatile memory packages 884 for storing data, and DRAM/ReRAM 886. Controller 882 includes FEP circuit888 connected to one or more BEP circuits 890. The one or more BEP circuits 890 connect to the non-volatile memory packages 884. One example of FEP circuit888 is depicted in FIG. 9. One example of BEP circuit 890 is depicted in FIG. 4. The embodiment depicted in FIG. 13B includes multiple (or distributed) compute engines, such that compute engine 892 is positioned in controller 882 and a set of compute engines (with built-in ECC engine) 894 are positioned in non-volatile memory packages 884. For example, compute engine 892 is a standalone ASIC that is connected directly to the toggle mode (TM) channels from the BEP circuits (the interface between the BEP circuits and the memory packages/die). Compute engine 892 can also be connected to the high speed, high-bandwidth DRAM memory 886 through a standard DDR interface to the DRAM/ReRAM chip and to FEP circuit888. Compute engine 894 is integrated with each memory package. In one embodiment, the memory package also includes an error correction engine (or at least the decoder portion of the ECC engine) to decode code words read from the memory and to correct the data read from the non-volatile memory die before being processed by the compute engine. Thus, compute engine 894 includes an ECC engine. In other embodiments, the compute engine can operate on data that has not been subjected to ECC decoding. The memory package can optionally include high-speed memory like DRAM to support the compute engine with access to temporary working data. As some data manipulation operations are within the memory package, the bandwidth available to the compute engine can be much higher than the toggle mode (TM) bandwidth available outside of the memory package. In some embodiments, the compute engines 892 and 894 will split up the work performed on the data. For example, code from the hosts can program the system to perform some operations on compute engine 892 and other operations on compute engine 894. For instance, the compute engine 894 could perform error correction coding (ECC) function along with simple application level tests, and the compute engine 892 could be executing a flash translation layer (FTL) optimized for sequential or indexed-sequential workloads, along with more complex filtering, sorting and grouping functions at the application query level.

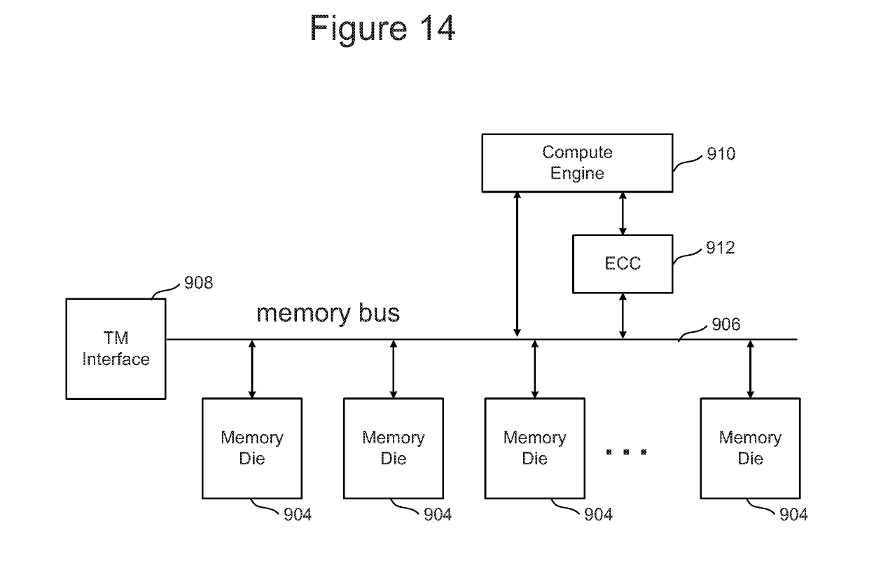

FIG. 14 is a block diagram of one embodiment of a memory package that includes a compute engine. The embodiment of 14 can be used to implement one of the memory packages 854 in FIG. 13A or memory packages 884 of FIG. 13B. The memory package of FIG. 14 includes a plurality of memory die 904 connected to a memory bus 906 (analogous to the memory bus of FIG. 5). Memory bus 906 is connected to a TM interface 908 for communicating with an BEP circuit. Additionally, FIG. 14 shows a compute engine 910 connected to the memory bus and to an error correction (ECC) engine 912. The ECC engine 912 is also connected to memory bus 906. Memory read from a memory die can be subjected to ECC decoding (including fixing errors) and then presented to the compute engine 910 to perform any of the compute operations discussed herein.

FIG. 15 is a block diagram of one embodiment of a solid state drive 950 that comprises a controller 952, non-volatile memory packages 956 for storing data, DRAM/ReRAM 954, and a compute engine near the location of that data that can be used to perform common data manipulation operations. Controller 952 includes FEP circuit960 connected to one or more BEP circuits 962. The one or more BEP circuits 962 connect to the non-volatile memory packages 956. One example of FEP circuit960 is depicted in FIG. 9. One example of BEP circuit 962 is depicted in FIG. 4. The embodiment of FIG. 15 implements memory package level integration. For example, each memory package includes multiple memory die and a compute engine 970 integrated within each memory die 972. In one embodiment, the compute engine will include an error correction engine to decode (including correcting) data read from the memory die. The error correction engine can be part of the compute engine or separate from the compute engine but otherwise included in the memory die.

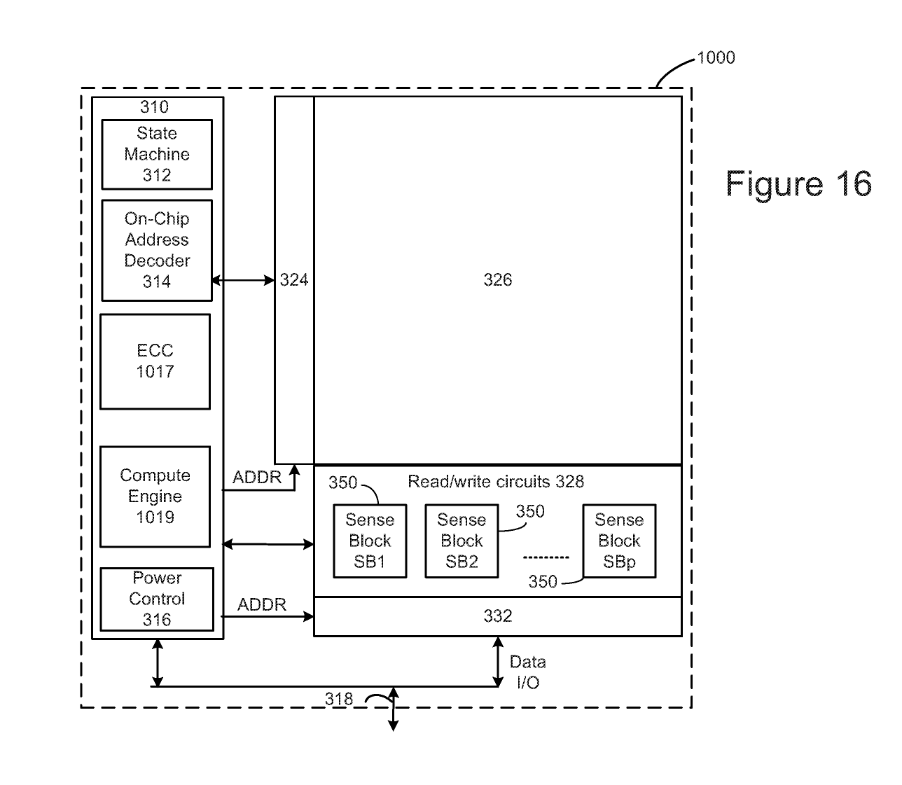

FIG. 16 is a block diagram of one embodiment of a memory die 1000 that includes a compute engine. For example, the memory die 1000 is an example implementation of memory die 972 of FIG. 15. The embodiment of FIG. 16 includes the elements of the embodiment of FIG. 6. For example, memory die 1000 includes a three dimensional memory structure 326 of memory cells (such as, for example, a 3D array of memory cells), control circuitry 310, read/write circuits 328, row decoder 324 and column decoder 332. Control circuitry 310 includes state machine 312, on-chip address decoder 314 and a power control module 316. Additionally, in the embodiment of FIG. 16, control circuitry 310 further includes error correction engine ECC 1017 and compute engine 1019. Data read from the memory structure 326 is decoded using error correction engine ECC 1017 and provided to compute engine 1019 for performing various compute operations, as discussed herein.

While the embodiments discussed above show the SSD controller to be implemented as a two ASIC solution containing a BEP ASIC and a FEPASIC, it is also possible that the SSD controller is implemented with more or less than two ASICs. In that case, the design space can be expanded to place the compute engine within any one or more of the ASICs. Additionally, the compute engine can be placed outside of the ASICs. In other embodiments, the SSD controller can include different architectures, other than the FE/BEP architecture. Even in the other architectures, the SSD controller can still be configured to include a compute engine inside one of the ASICs or circuits or modules. Additionally, a compute engine can be added to SSDs that are not implemented using ASICs, but implemented using other hardware.

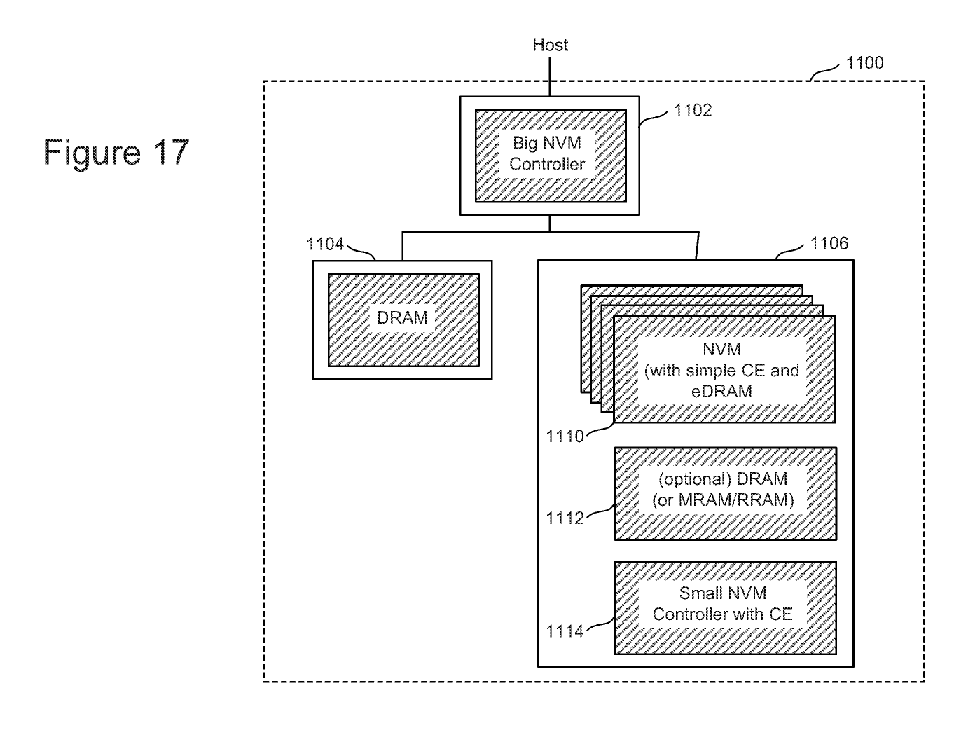

The embodiment of FIG. 15 includes integrating the compute engine within the memory die (such as a NAND memory die or ReRAM memory die). FIG. 17 is a block diagram providing additional details for implementing an embodiment of the system of FIG. 15. Specifically, FIG. 17 shows a host in communication with a SSD 1100 (implemented on a printed circuit board) that includes a Big NVM controller 1102 and a Small NVM controller 1114. The Big NVM controller 1102 is in communication with DRAM 1104 and memory package 1106.

In one embodiment, memory package 1106 includes several memory dies 1110, optional DRAM (or MRAM/RRAM/PCM/eDRAM) 1112, and Small NVM Controller 1114. Each of the memory die 1110 has an on die compute engine (CE). In one embodiment the on die compute engine is implemented using CMOS technology on the top surface of a substrate and under the monolithic three-dimensional memory array. Potentially, eDRAM/STT-MRAM/PCM as well as SRAM can be integrated. The on-die compute engine (CE) can perform some of the data manipulation operations.

In one embodiment, Small NVM Controller 1114 includes a compute engine (CE) that can perform some of the data manipulation operations. Small NVM Controller 1114 can communicate with the internal memory dies and external chips (i.e. Big NVM controller and DRAM in FIG. 17). Optional DRAM 1112 is used for the Small NVM Controller 1114 to store working data sets. By off-loading computation from the Big NVM Controller 1102 to Small NVM controller with a computer engine (CE) 1114 and the simple CE of the memory die 1110, the external DRAM requirement and communication overhead can be reduced.

FIG. 17 shows that each of Big NVM Controller 1102, DRAM 1104, memory die 1110, DRAM 1112 and Small NVM Controller 1114 can be implemented on separate silicon die in three different packages mounted on one printed circuit board. Thus, FIG. 17 provides a big and small NVM controller architecture. The Big NVM Controller 1102 interfaces with the host and DRAM. The Small NVM Controller 1114 can be inside any of the memory packages. The Small NVM Controller 1114 includes a computational engine with optional DRAM and manages multiple NVM channels. A mapping table can be stored in the optional DRAM (or MRAM/PRAM).

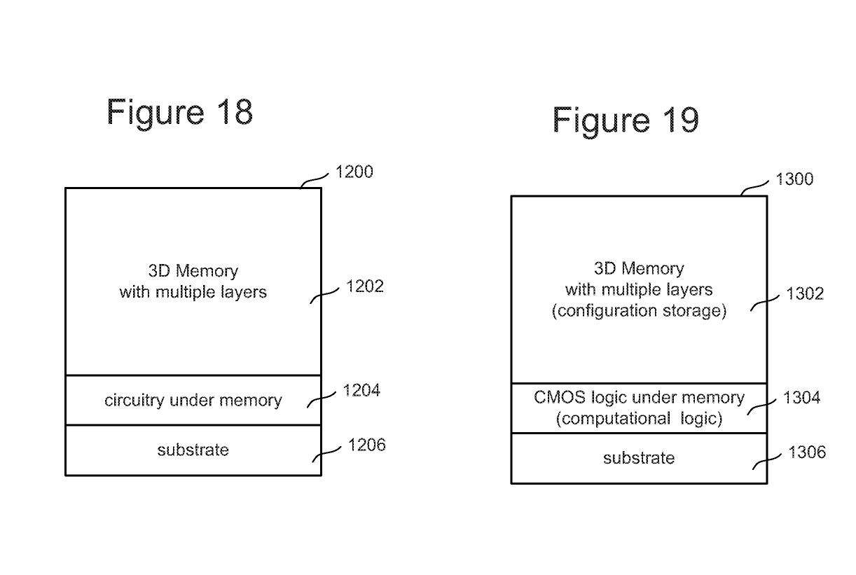

FIG. 18 is a block diagram of one embodiment of a memory die 1200 with circuitry under the memory array. FIG. 18 shows a monolithic three-dimensional memory structure 1202 with multiple layers. Underneath the memory structure 1202 is circuitry 1204 that is implemented on the top surface of the substrate 1206 and under the memory array 1202. In one embodiment, the circuitry 1204 is implemented using CMOS technology. For example, simple computational logic can be integrated in the CMOS logic under the memory array 1202 potentially with eDRAM/STT-MRAM/PCM as well as SRAM/latches. Simple circuitry logic (i.e., randomizer, ID generator, PUF, or AES) and simple error management logic (i.e., error location map or a simple error avoiding algorithm such as read reference optimizer) as well as ECC can be integrated in the CMOS logic under the memory array 1202 as examples of the compute engine discussed above. This improves latency and performance by eliminating data transfer overhead from the memory die to the separate controller die. An FPGA could be integrated, supporting multiple configurations with a single system on a chip as an aforementioned compute engine. An FPGA can be integrated, supporting multiple configurations within a system on a chip.

Additionally, other functions can be integrated as an aforementioned compute engine. For example, a CPU or parallel computational engine can be integrated as an aforementioned compute engine. An SIMD engine (“GPU”), neural network, DSP engine (e.g., image/audio processing), digital logic operation (multiplication, addition, subtraction, XOR, etc.), data mining (apriori, k-means, pagerank, decision tree) or pattern matching (i.e., Hamming distance calculation), FPGA fabric supporting multiple configurations in the memory die, high speed I/O circuits with memory equalizers, circuits for optical or capacitor/inductive coupling based on interconnections can also be used. In one embodiment, the compute engine needs to be able to work with encrypted data when AES is bypassed for specific applications. In some embodiments, the compute engine may need to work with erroneous data when ECC is bypassed for specific applications

FIG. 19 is a block diagram of one embodiment of a memory die 1300 with circuitry 1304 under the memory array 1302 for using the non-volatile memory die 1300 as a non-volatile-FPGA. The memory die 1300 will include a three-dimensional monolithic memory array 1302. Implemented on the top surface of the substrate 1306, and under the memory array 1302, will be CMOS logic 1304 that implements a FPGA to be used as a compute engine (per the discussion above). This system will use the memory array 1302 (NAND or other type of non-volatile memory) as configuration storage for the reconfigurable logic 1304 of the FPGA. That is, configuration data stored in memory array 1302 is used to configure the FPGA's. This will make the FPGA non-volatile. This will allow for fast boot up compared to conventional FPGAs, which require a reading of configuration data from a discrete nonvolatile memory device to the volatile FPGA cell array. When the FPGA (hardware accelerator/compute engine) is not needed, the configuration storage (the memory array) can be used as just normal non-volatile storage, saving idle power.

Turning now to the error correcting codes (ECCs) and databases in more detail, a record in database may consist of multiple fields. A query may test certain fields and select the records satisfying the conditions. Also, the query may retrieve only some of the fields in the selected records.

Under previous arrangements, one or multiple records are typically included in an ECC codeword. In traditional ECC schemes, such as LDPC or BCH codes, all bits in the ECC codeword need to be decoded before any decoded bits are generated. Hence, even if the query only involves a few fields, the entire record needed to be decoded. Decoding complexity and power are wasted over those irrelevant fields, and this prevents very high data throughput from being achieved.

An application-aware ECC scheme can exploit knowledge about the database schema and data queries, and decode only the fields relevant to the query. For example, the logical and physical database schema, including the size of database rows, number of columns or fields and their sizes, and whether the layout is row-oriented or column-oriented may be available to the error correction engine. Alternately, or additionally, in some embodiments the decoder can be informed on a query-by-query basis about the set of fields (or columns of records) that will be: used in test conditions (such as in the SELECT . . . WHERE expressions) by the query; projected for retrieval from the SELECTed rows according to the query; and/or don't cares (logical, numerical, branch and bound). The ECC algorithm may optionally be aware of a test evaluation order to use in searching a database, such as “condition on column A will be tested before condition on column B”.

In one set of embodiments, the application-aware ECC schemes presented here can use a translator that converts data queries into which subcodes to decode and in which order. This can be done according to information regarding the database, such as the selectively of each column. These meta-data can, for example, be stored in the memory along with the database. In this case, to generate the application-aware decoding instructions, the system can either pass the data query to the memory controller, in which the converter is located, or the meta-data can be passed to the compute engine to have the converter implemented there, or some combination of these. The generation of the application-aware decoding instructions using a compute engine at or near the error correction engine can further increase the rate of data throughput.

Two ECC schemes are described to decode only the fields relevant to the query while ignoring the others as much as possible. They are integrated interleaved (II) codes and product codes. Compared to traditional ECC schemes that decode the entire records before any fields to be used by the analytics are available, the application-aware ECC schemes can achieve orders of magnitudes throughput improvement and/or substantially lower decoder complexity.

A number of differing arrangements for memory systems and the placement of error correction engines within these systems have been described above. For example, the error correction engine to generate and decode the ECC codewords can be within the controller (FIG. 1), in the flash manager (FIGS. 2, 4, and others), in the memory package (FIG. 7), or on the memory chip (FIGS. 15 and 16). The ECC schemes presented in the following examples can be used with any of these arrangements; however, allocating computing resource close to the storage elements can help to increase the rate of data throughput of these data analytics. Similarly, placement of a compute engine for generation of the application-aware decoding instructions close to the ECC engine can further increase the rate of data throughput. In other embodiments, the ECC decoder may be implemented by multiple parts located in different parts of the memory system. For example, when the integrated interleaved codes are used, the part for decoding individual subcodes can be put in the memory package, and the part for decoding using shared, higher level parities can be put in the flash manager, since it has higher complexity and is activated with low probability.

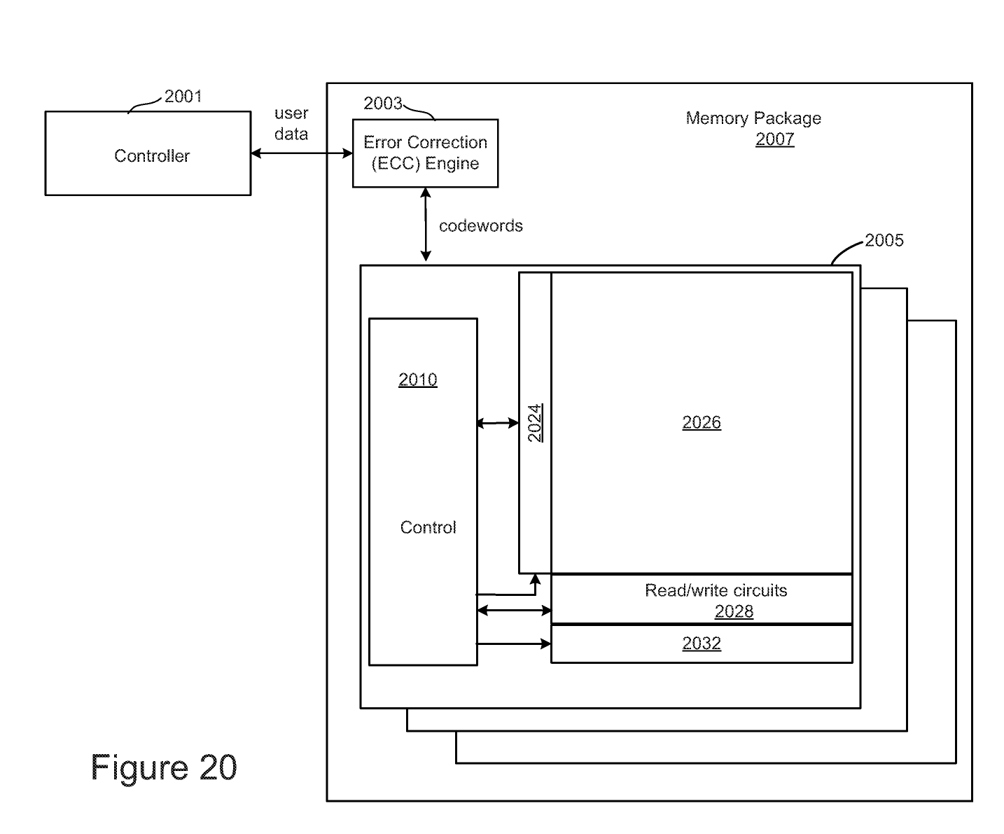

FIG. 20 is a block diagram to illustrate some of the elements involved in embodiments for the implementation of application aware error correcting codes. FIG. 20 is a simplified version of FIGS. 13A, 13B, and 15, showing a controller 2001 connected to a memory package 2007 including an error correction engine 2003 and memory dies 2005. The error correction engine 2003 is connected to receive user data from the SSD controller 2001, form the user data into codewords which are then transferred to one of the memory dies 2005. The error correction engine 2003 is taken to represent both the encoder and decoder portions of the error correction, or ECC, engines. Depending on the embodiment, the encoding portion of the error correction engine 2003 and decoding portion of the error correction engine 2003 can use separate hardware components or share some or all of their hardware components. In response to a request for a field of a database stored in the memory dies 2005, the error correction engine 2003 receives and decodes the codewords and supplies the requested field to the controller. In FIG. 20, the error correction engine is shown as being part of the memory package, but in some embodiments an error correction engine can also be included in the controller 2001, as illustrated in FIG. 12. For example, if an initial decoding by the error correction engine 2003 is unsuccessful and more powerful decoding is needed, the codeword can be sent a more powerful error correction engine on the controller 2001 for decoding.

The memory dies 2005 include an array of memory cells 2026, along with the control circuits 2010, decoders 2024 and 2032, and read/write circuits 2028 to program the codewords into the memory cells, such as discussed above in more detail with respect to FIG. 6 or 16, for example. When reading out data, the control circuits 2010, decoders 2024 and 2032, and read/write circuits 2028 read out the codewords to the error correction (ECC) engine 2003, which decodes the code word. In embodiments described below, the codewords can be formed according to the Integrated Interleaved (II) codes or product codes.

More specifically, the data is processed, analyzed, or both, next or close to the storage, and only the results are sent through the path to the controller and the host, which has limited bandwidth. For example, the error correction engine may be located in the same package, or even on the same die, as the memory storage elements. Such in or near storage computing not only bridges the discrepancy between the very high throughput required by big data analytics and the limited storage device bandwidth, but also substantially reduces the energy needed for moving the data across the storage stack.

As error-correcting codes (ECCs) are used to help ensure data integrity, data read from NAND or other storage media will pass through error-correcting decoders to correct possible error before they are involved in any computation and analytics. To match the high-speed in or near storage data processing, the ECCs may need to run at high throughput rates (e.g., 10 GB/s or higher). Such a high throughput is very difficult to achieve by traditional ECC schemes even if possible advancements of integrated circuit technology are taken into account.

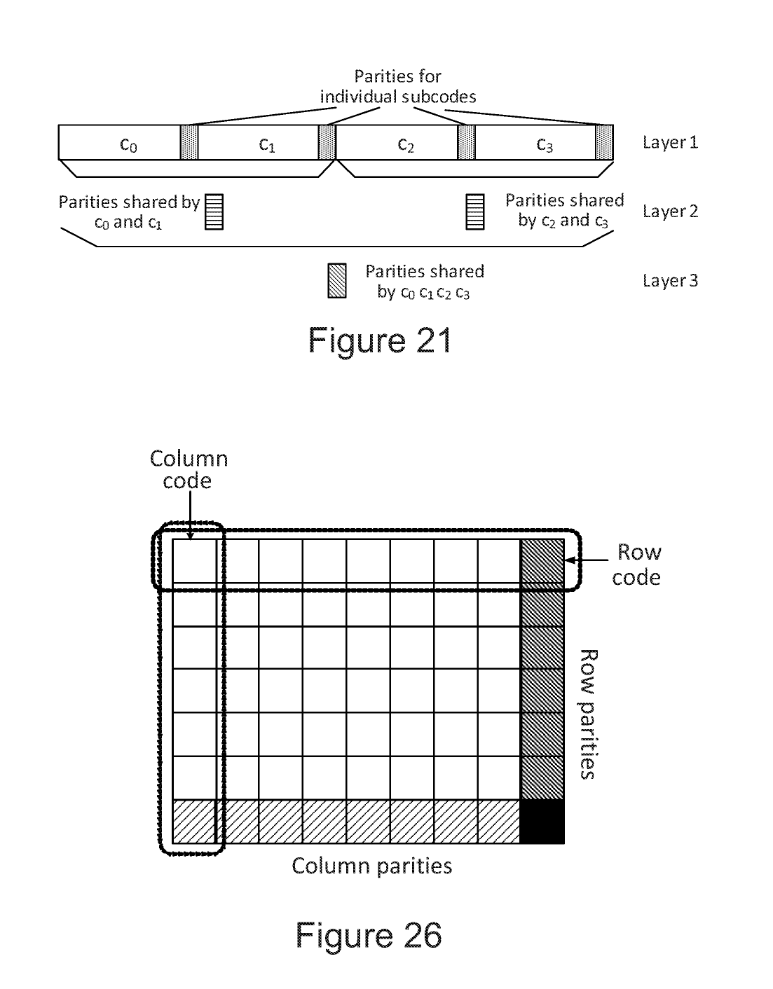

An ECC codeword is formed of a set of user data and a corresponding set of parities, that are generated by the ECC engine. The codeword, both user data and corresponding parities, are written together and read back together, so that the parities are available if needed to correct the data when read. Considering the use of application-aware Integrated Interleaved (II) codes, this approach divides up a codeword into subcodes. The structure of an example II code is shown in FIG. 21.

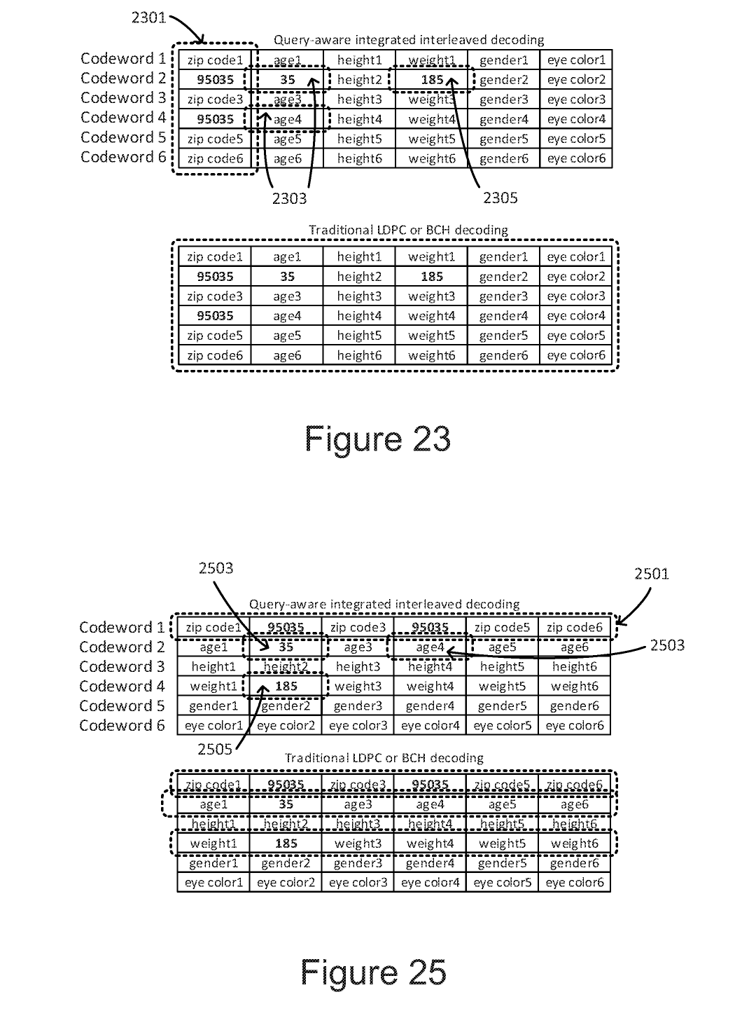

As shown in FIG. 21, a codeword is divided into multiple subcodes. In the example shown in FIG. 21, there are four subcodes and they are denoted by c₀, c₁, c₂, c₃, although other numbers of subcodes can be used as discussed further below. A codeword can be divided into more subcodes depending on the desired decoding granularity, redundancy, and correction capability of the error correction engine, among other factors. Each subcode may correspond to one or a few fields in a record, and may be a BCH code for example. For example, referring to Codeword 1 at the top of FIG. 23, this shows an example of 6 data fields, where each field can correspond to a subcode of the field data and its corresponding layer 1 parity. Each subcode has local parities that can be used to correct certain number of errors. Additionally, shared parities are added to the subcodes in a hierarchical manner to correct more errors. In the example of FIG. 21, in layer 2, c₀ and c₁ share additional parities, and c₂ and c₃ share additional parities. After generating the layer 1 parities and form the subcodes, the error correction engine generates the layer 2 parities shared by multiple subcodes. The parities shared by each group can be multiple parities. The layer 3 parities are shared by all subcodes of the codeword, and are generated to cover the full codeword by the error correction engine based on the used data and lower level parities. In this case, if, for example, the error in c₀ is not correctable by using its local parities in layer 1, then the parities in layer 2 are utilized. If the errors are beyond the correction capability of the layer 2 parities, then the parities in layer 3 are used. Since the parities in layer 3 are shared and generated according to all subcodes of the codeword, all subcodes are involved in the decoding in order to utilize the parities in layer 3. This embodiment shows one intermediate parity level (layer 2) between the lowest level subcodes (layer 1) and the full codeword parity level (layer 3), but other numbers of layer can be used in other embodiments.

A number of ECC schemes are known. For example, generalized integrated interleaved (II) codes based on BCH and Reed-Solomon (RS) codes allow more flexible use of the shared parities. Standard BCH and RS codes require minimum redundancy in order to correct a given number of errors. Unlike LDPC codes, BCH and RS codes can have very short codeword length, such as a few bytes. As a result, the II codes based on BCH or RS codes can more readily be adopted to locally decode selected fields of the database records, while ignoring the other irrelevant fields. Only when the numbers of errors in the selected fields exceed the correction capabilities of the corresponding subcodes, other subcodes not related to the query are involved in the decoding in order to utilize the shared parities to correct more errors. If sufficient local parities are allocated to each subcode, the probability of utilizing the shared parities and involving other fields irrelevant to the query is low. When the selectivity of the query is low (i.e., a small proportion of the records satisfy the testing condition) and/or a small number of fields are needed in the query, such II codes may improve the decoding throughput by several orders of magnitudes compared to traditional ECC schemes that have to decode every bit in the codeword.

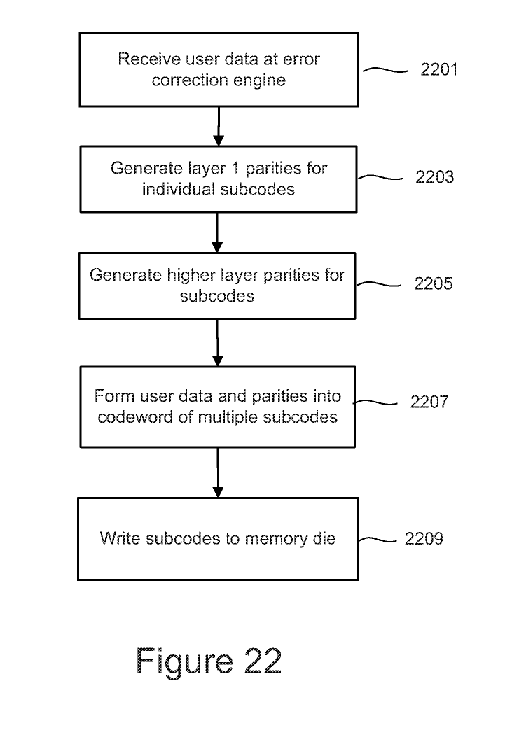

FIG. 22 is a flowchart describing one embodiment of writing user data that is encoded using an integrated interleaved code into a memory die. At step 2201, the error correction engine receives the user data for encoding, where the user data can be fields of a database or more general data. At step 2203, the parities are formed for the individual layer 1 subcodes of a codeword. In the main embodiments discussed below, each subcode corresponds to a field of a record of a database and the layer 1 parity corresponds to the single corresponding field. In other embodiments, a subcode may correspond to more than one field, or a filed may run across several subcodes. At step 2205, the higher level parities for the codeword are formed, including any intermediate parities covering several subcodes, as in the layer 2 parities in FIG. 21, and the top level parities corresponding the whole of the codeword, as in layer 3 of FIG. 21. Although steps 2203 and 2205 are shown as separate steps in FIG. 22, the parities in different layers may be generated concurrently in some embodiments. The subcodes and higher layer parities are formed into a codeword at step 2207, after which it is transferred to the memory dies and written in the memory dies at step 2209.

Embodiments of an application-aware II decoding can be carried out as follows:
i) First decode only the subcodes containing the fields to be tested by the query, such as those after the ‘WHERE’ expression in the example below.
ii) In the records satisfying the test conditions, only decode the fields requested by the query, such as those after the ‘SELECT’ expression.
   In both of the above steps, the shared parities and other contributing subcodes are only involved in the decoding when necessary.

As an example of the application-aware II decoding, consider a database consisting of records that have 6 fields: zip code, age, height, weight, gender, and eye color. An example query is:
SELECT weight FROM table
   WHERE (zip=95035) AND (age BETWEEN 30 and 50)
      FIG. 23 looks at a row-oriented database example and FIG. 25 looks at a column-oriented database for this example.

FIG. 23 shows an example of application-aware II decoding for a row-oriented database, where each row includes the fields of an entry. Aside from the positive results for the queries in the examples below, the entries are just listed as a generic field (e.g., “age 1”). In this example, each record is protected by one codeword, and each field is encoded into a subcode. The subcodes in a codeword do not have to be the same size. In the examples used here, one codeword includes all the fields of one record; but, more generally, depending on the number and size of the fields, and the size of a full codeword, a single record may run over into more than a single codeword or, conversely, a single codeword may hold fields for several records.

To execute the query, the codewords are processed one by one or multiple codewords are processed simultaneously, depending on whether multiple codewords can be made available from the storage at a time. Looking at the top part of FIG. 23, in the “WHERE (zip=95035) AND (age BETWEEN 30 and 50)” example, for each codeword, first only the ‘zip code’ field (subcode) 2301 is decoded and tested, as illustrate by the dashed line around the first column. If ‘zip code’=95035, such as in record 2 and 4 2303 in FIG. 23, then the ‘age’ field in that record is decoded. Only when the age is between 30 and 50, the ‘weight’ field in that record 2305 is further decoded. In this example, the zip fields are decoded first, after which the relevant age fields are decoded, but the order could be reversed and the age fields decoded first followed by the zip fields. The order can be selected based on the relative numbers of expected results: for example, if the WHERE query was for zip code and gender, the zip query could be done first as this would likely return relative few subcodes to decode for the gender query; whereas doing gender first would be expected to return around half of the records, which would then need their zip field subcodes.

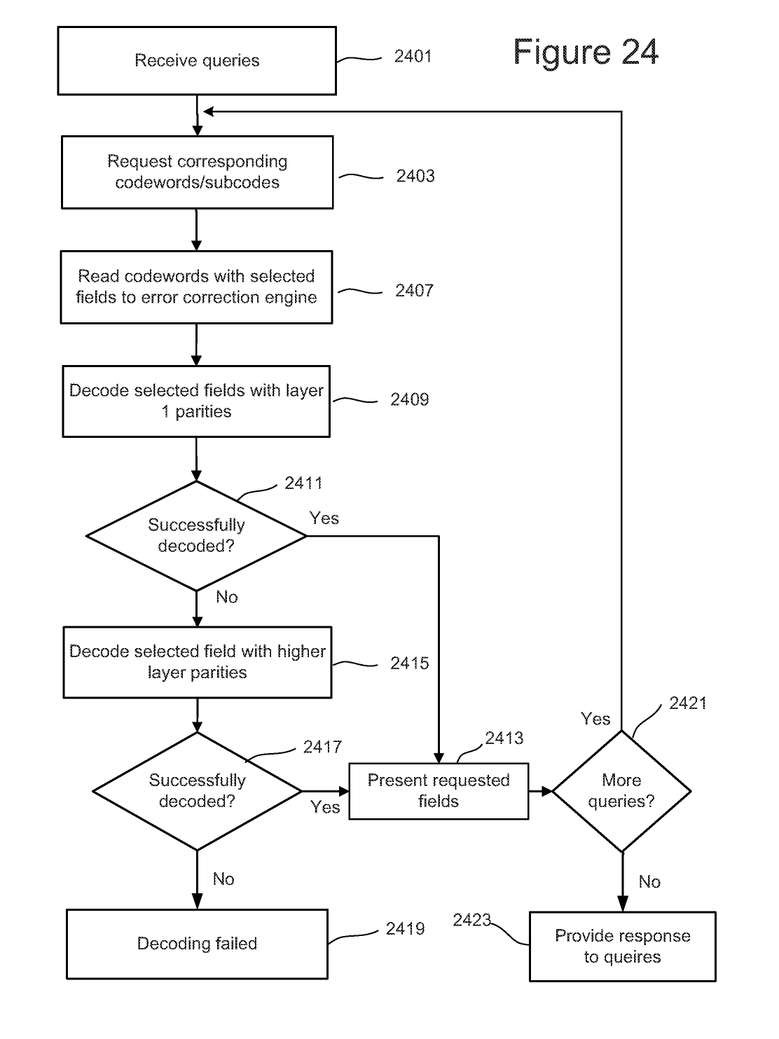

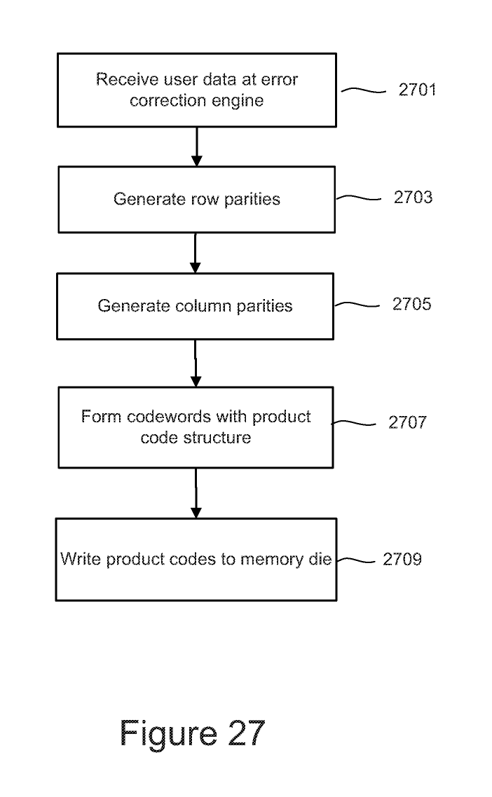

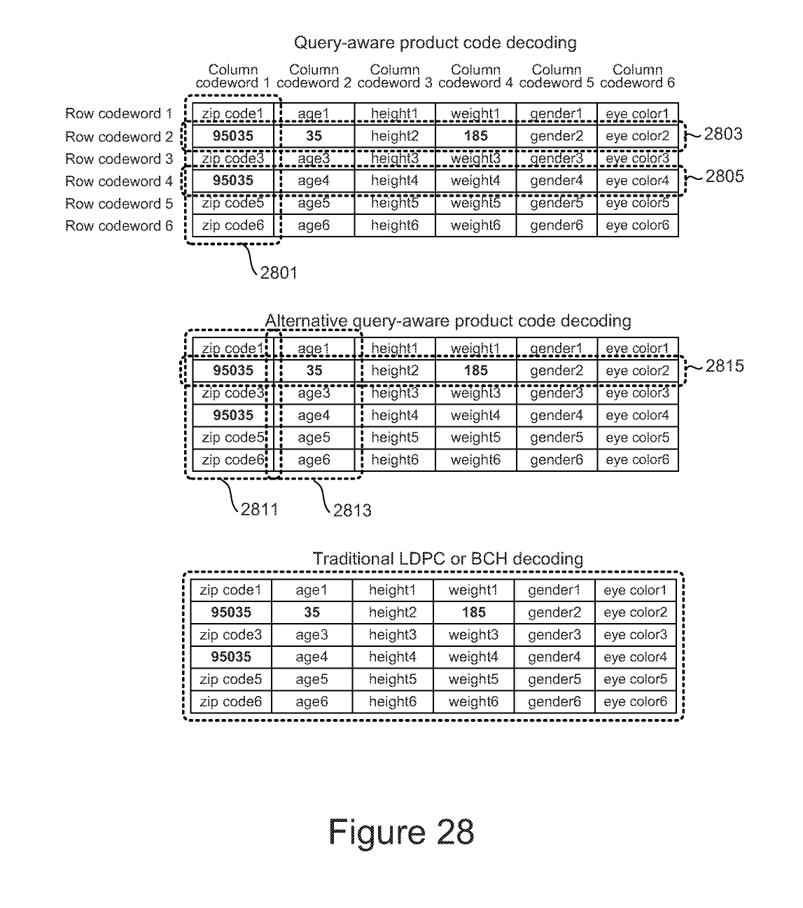

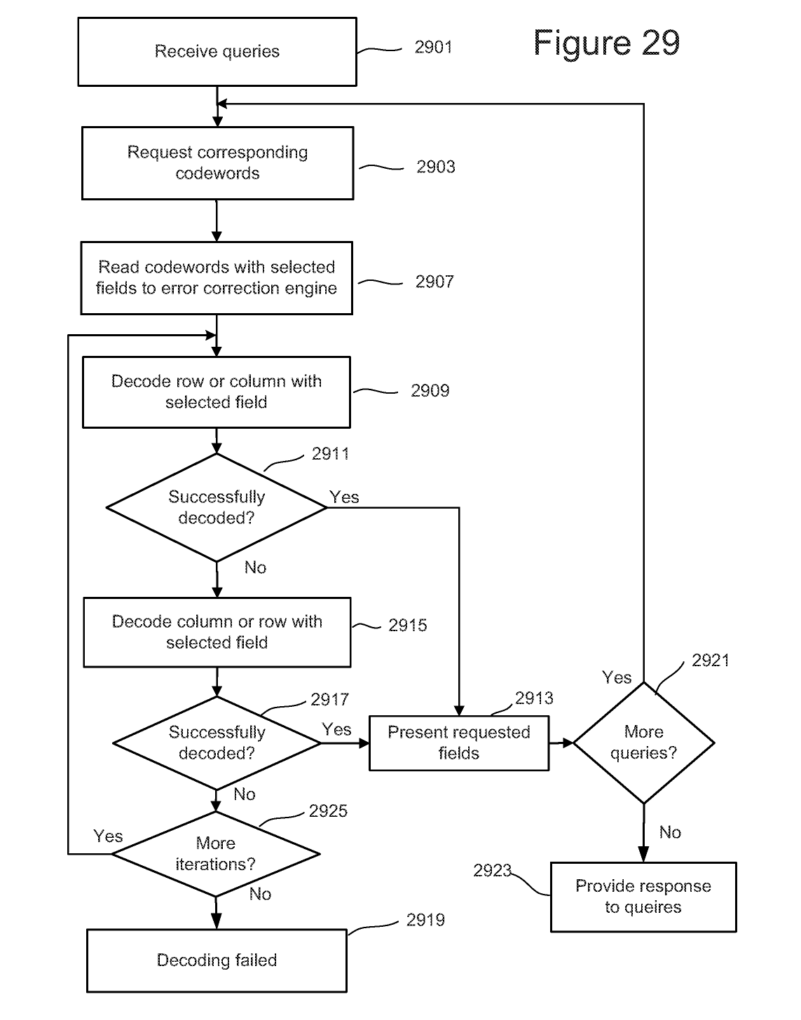

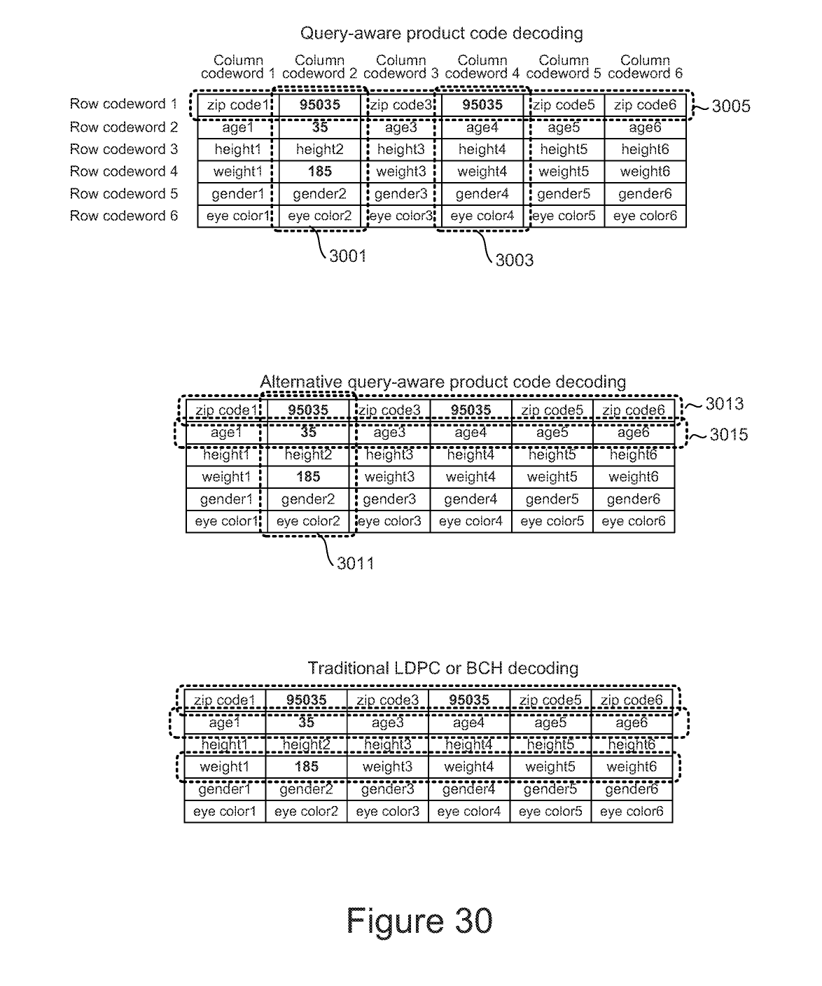

FIG. 24 is a corresponding flowchart describing one embodiment of reading user data that is encoded using an integrated interleaved code from a memory die. At step 2401, a set of one or more queries for the database, such as those just described with respect to FIG. 23 is received. At step 2403 a request for codewords or subcodes corresponding to the first query is made, with the codeword corresponding to the requested field read and passed on to the error correction engine at 2407. In the example of FIG. 22, this first request would be for “WHERE (zip=95035)” and the corresponding codewords are read out.

At step 2409, the subcode corresponding to the selected field is decoded using the layer 1 subcodes that are specific to the individual subcodes. In the example of FIG. 22, this corresponds to the decoding of first subcode (corresponding to zip codes), with the other subcodes of each codeword not being decoded. Step 2411 determines if the decoding was successful. If the subcodes for the requested fields can be successful decoded based on the layer 1 subcodes, the requested fields are presented at step 2413; if not, the subcodes that failed to decode are decoded using the higher layer parities at step 2415. When higher layer parities are used, other sub-codes that contribute to the higher layer parities, but which were not previously request by the query, may be involved in order to utilize the higher layer parities. Depending on the number of layers, this may take more clock cycles and involve more complex computations, using progressively higher layers, such as the layer 2 codes or layer 3 codes in FIG. 21. In some embodiments, the higher level decoding can be done in the error correction engine within the memory package, while in other embodiments the higher layer decoding can be performed by a more powerful error correction engine outside of the memory package, such as on the controller. If the decoding is found successful at step 2417, the requested field is presented at step 2413. If the decoding by the error correction engine using the higher layers is not successful, a requested subcode is found to be not decodable and an error status can be returned, corrective measure can be taken to extract the data, or both at step 2419.

From step 2413, the flow goes to step 2421 to determine whether there are more queries. In the example of FIG. 22, after the first query of “WHERE (zip=95035)”, the process is repeated for “WHERE (age BETWEEN 30 and 50)” query, where now just the subcode for the age field is decoded from codewords 2 and 4. Once fields corresponding to the age query are provided at step 2413, the process is again repeated, where the requested field is now the age field of codeword 2. As this is last of queries, the response to the queries is presented at step 2423.

In the top part of FIG. 23 illustrating query-aware integrated interleaved decoding, only the fields circled by the dashed lines are decoded, assuming the number of errors in each field is within its correction capability. Comparatively, if traditional ECC schemes are adopted, all fields in all codewords need to be decoded, as represented by the dashed line in the bottom portion of FIG. 23.

The application-aware II codes can be also applied to column-oriented database, as can be illustrated with respect to FIG. 25. It should again be noted that the same field from all records may form multiple codewords, and the sizes of different fields may vary. To execute the example query, first the codewords for the ‘zip code’ fields (codeword 1 2501) are decoded. The indices of the records whose zip codes equal to 95035 are put into a list. Then in the codewords for the ‘age’ field, only the subcodes 2503 whose indices are in the list are decoded. The list is updated to include only the indices of the records whose age is between 30 and 50. After that, in the codewords for the ‘weight’ field, only the subcodes 2505 whose indices belong to the updated list are decoded. Higher layer parities are only used if the lowest layer parity is insufficient for the decoding: for example, if the code word of the “age” subcode fails to decode for codeword 2, it may be needed to go up to the layer 2 parity shared by the age field; and if this still fails to decode, it may further be needed to go to a layer 3 parity of the whole codeword. In most cases, however, it is expected that only the layer 1 parities of the individual subcodes will be needed.

The codewords/subcodes decoded in this process are circled by the dashed lines in top part of FIG. 25. If traditional ECC schemes are adopted, then the entire codewords for the ‘zip code’, ‘age’ and ‘weight’ fields are decoded as shown in the lower portion of FIG. 25. Hence, the application-aware II codes also help to improve the decoding throughput in the case of columnar database. Although described above with respect to the row-oriented database shown in FIG. 23, the flowchart of FIG. 24 also corresponds one embodiment of reading user data that is encoded using an integrated interleaved code using a column-oriented database, the difference being in the choice and order of queries.

Turning from integrated interleaved (II) codes to product codes, FIG. 26 illustrates the structure of product codes, where the fields are logically organized to form a two-dimensional array of rows and columns. Parities are independently generated for each of the rows and each of the columns, so that in addition to row forming a codeword, each column also forms a codeword. Consequently, a field can be extracted either from its row codeword or its column codeword. In the case that the errors are not correctable by individual row (column) code, the column (row) decoding is activated. This also allows for row and column decoding to be applied iteratively to correct more errors: for example, if a row is not decodable but some of the column are, column-decoded entries of that row possibly reduce the row error sufficiently to allow it to be decoded. After the column decoding, if some of rows become decodable but there are still some other rows that are undecodable, then the column decoding can be carried out again. This process is repeated until the decoding of all codewords are successful or this iterative column-row decoding does not lead to new decodable codewords, in which case a decoding failure is declared. Additionally, being able to choose between row decoding and column decoding for a given field adds to flexibility, as the most efficient decoding choice can be selected: for example, in a column oriented database, only the column corresponding to a query would need to be decoded.

A relatively larger number of records, which can vary depending upon the size of the records, can be put into a codeword of the product code. Assume, for example, that the database is row (column) oriented: To achieve application-aware decoding, first the column (row) codewords consisting of the fields to be tested by the query, such as those after the ‘WHERE’ expression, are decoded. Then the row (column) codewords consisting of the records satisfying the test conditions are decoded. The other rows and columns are only decoded when the numbers of errors exceed the correction capability of individual rows and columns, whose probability should be low. Although the decoding is applied to the entire row or column codewords, and hence the decoding granularity is coarser than that in the application-aware II codes, only those codewords relevant to the query are decoded. Therefore, the application-aware product codes can also achieve substantial throughput improvements over traditional ECC schemes.

FIG. 27 is a flowchart describing one embodiment of writing user data that is encoded using a product code structure into a memory die. At step 2701, the error correction engine receives the user data for encoding, where the user data can be fields of a database or more general data. The data is logically structured into rows and columns of a product code, with the row parities being formed at step 2703 and the row parities formed at step 2705. Although shown as separate steps 2703 and 2705 in FIG. 27, the encoding portion of the error correction engine may execute steps 2703 and 2705 concurrently. At step 2707, the database fields, or other user data, and the corresponding row and column parities are organized into the product code structure of row codewords and column codewords, after which they are transferred to the memory dies and written at step 2709.

Considering the same query example as in FIGS. 23 and 25, an example of an application-aware product code decoding for a row-oriented database is shown in FIG. 28. In this example, a row codeword consists of one record, such as Row codeword 2 2803 or Row codeword 4 2805. This scheme also applies if a portion of a record or multiple records are put into each row codeword, as long as the same fields from different records are aligned to the same columns among the row codewords. A column codeword is not limited to one field from each record, as shown in FIG. 28. It can be formed by multiple fields or a portion of a field from each record depending on the sizes of the fields, the length of the column code, the number of row codewords in a product codeword, and so on.

As shown at the top of FIG. 28, to process the example query, first the column codeword 2801 corresponding to the ‘zip code’ field is decoded. If the number of records whose zip code=95035 is small, row decoding is applied to all those selected rows (row codewords 2 2803 and row codeword 4 2804) as shown in the first chart of FIG. 28. From the row decoding results, the ‘age’ field of column 2 is tested for rows 2 and 4 for those records with age between 30 and 50, with row codeword 2 passing. The ‘weight’ field is output for those records with age between 30 and 50, at column 4, row 2 with the value of 185.

FIG. 29 is a corresponding flowchart describing one embodiment of reading user data that is encoded using a product code structure from a memory die. At step 2901, a set of one or more queries for the database, such as those just described with respect to FIG. 28 is received. At step 2903 a request for codewords or subcodes corresponding to the first query is made, with the codeword corresponding to the requested field read and passed on to the error correction engine at 2907. In the example of FIG. 28, this first request would be for “WHERE (zip=95035)” and the corresponding codewords are read out and column 1 decoded to answer the query. At step 2909, the subcode corresponding to the selected field is decoded. Depending on the query, this can either be a column decoding or a row decoding. Referring back to the top portion of FIG. 28, the first query for zip code values can use a column decoding corresponding to the fields circled at 2801, while the subsequent age and weight queries can be based on row decoding of the fields circled at 2803 and 2805.

Step 2911 determines if the decoding was successful. If the codewords for the requested fields can be successful decoded, the requested fields are presented at step 2913; if not, at step 2915 the codewords that failed to decode by column decoding at step 2909 are decoded using rows; and codewords that failed to decode by row decoding at step 2909 are decoded using columns. If needed, this can be done in an iterative manner, where, for example, a partial row decoding can be applied to subsequent column decoding. If the decoding is found successful at step 2917, the requested field is presented at step 2913. If the decoding by the error correction engine using alternate column or row decoding is not successful, another iteration may be performed. At alternate step 2925, it is determined whether more iterations are to be performed and, if so, the flow loops back to step 2909. If the decoding by the error correction engine using alternate column or row decoding at step 2917 is not successful and the number of iterations has reached a limit at 2925, a requested codeword is found to be not decodable and an error status can be returned, corrective measure can be taken to extract the data, or both at step 2919.

From step 2913, the flow goes to step 2921 to determine whether there are more queries. In the example of FIG. 28, after the first query of “WHERE (zip=95035)”, the process is repeated for “WHERE (age BETWEEN 30 and 50)” query from codewords 2 and 4. Once fields corresponding to the age query are provided at step 2913, the process is again repeated, where the requested field is now the age field of codeword 2. As this is last of queries, the response to the queries is presented at step 2923.

Alternatively, if the number of records whose zip code=95035 is relatively large, another column decoding on the ‘age’ field can be carried out to further reduce the number of selected records before the row decoding is carried out. The flow for this process is the same as is FIG. 29, but where the order of queries is different than described above for the top chart of FIG. 28. This alternative decoding process is shown in the second chart of FIG. 28. Both of column 1 codeword 2811 and column 2 codeword 2813 are now decoded prior to decoding row 2 2815. Those column and row codewords decoded are circled by the dashed lines. Although the irrelevant fields in the selected records are decoded, the unselected records are not decoded in this application-aware product code decoding. Compared to the traditional ECC schemes that decode every field in every record as shown in the third chart of FIG. 28, significant throughput improvement is also achieved.

FIG. 30 considers an example where the records are stored in a column-oriented manner, where the top chart shows one example of a query-aware product code decoding, the middle chart shows an alternate example of a query-aware product code decoding, and the bottom chart a traditional LDPC of BCH decoding. As shown in the top chart of FIG. 30, to execute the example query, first the row codeword 1 3005 consisting of the ‘zip code’ field is decoded. From the decoding result, the indices of the records whose zip codes are 95035 are put into a list. Then the column codes consisting of the records in the list (column codeword 2 3001 and column codeword 4 3003) are decoded as shown in the first chart of FIG. 30.

Alternatively, if the number of records in the list selected based on the zip code alone is large, then the row codewords corresponding to the ‘age’ field is decoded to further reduce the list of the selected records before column decoding is carried out for any records, as shown in the second chart of FIG. 30. In this example, both row codeword 1 3013 and row codeword 2 3015 are decoded, after which column codeword 2 3011 is decoded. Depending on the lengths of the row and column codes, the selectivity of the fields, and the number of fields involved in the query, such application-aware product codes may still decode fewer bits and achieve higher throughput than the traditional ECC schemes for columnar database. Compared to the traditional ECC schemes that decode every field in all needed codewords, as shown in the third chart of FIG. 30, significant throughput improvement is also achieved.

For either the query-aware decoding in the top chart of FIG. 30, or the alternate query-aware decoding described with respect to the middle chart of FIG. 30, the flow for this process can again be the same as is FIG. 29, but where the order of the queries is different than described above for the top chart of FIG. 28.

Unlike traditional ECC codes, the application-aware schemes make use of the specifics of the database schema and analytic queries. Only the fields relevant to the query, as opposed to all fields and all records in conventional ECC schemes, are decoded in most of the cases. For big data analytics, most often only a very small portion of the records are selected based on the tests over a small number of fields. Hence, the application-aware schemes may improve the decoding throughput or complexity by several orders of magnitudes.

The use of application-aware ECC can be implemented for any of the placements of ECC engines described in the earlier portion of the above description, including within the memory system's controller, such as is illustrated in FIG. 1. The closer that the ECC engine, or some its function, are located relative to the memory cells, however, the less the amount of data that needs to be shifted over intervening bus structures. By placing the ECC engine within the memory package as in FIG. 13A or 13B, for example, only the query needs to be sent onto the package and only the result needs to be sent out. This can greatly reduce the amount of data transferred over the bus between the controller and memory packages. On the other hand, this requires the ECC engine to have high throughput rates (e.g., 10 GB/s or higher) to match the high-speed large data transfers internal to the memory packages. Similarly, moving the ECC onto the memory die as in FIG. 15 allows for the process to all occur on-chip, further increasing speed, but requiring a more specific chip structure.

According to one set of embodiments, a memory system includes an error correction engine and a memory package connected to the controller. The memory includes an error correction engine, one or more non-volatile memory dies, and one or more control circuits. The error correction engine is configured to form a user data set including a plurality of data fields into a codeword, the codeword including the user data set and corresponding parities generated by the error correction engine. In response to a request for one of the data fields of the codeword, the error correction engine is configured to decode and provide the requested data field without providing other data fields of the codeword. The control circuits are connected to the error correction engine and the memory dies, and configured to program the codeword into the memory dies and read the codeword from the memory dies.

In other of embodiments, a method includes receiving from a controller a request for a data field of a database at a memory package, reading a codeword containing the requested data field is read from a memory die in the memory package, where the codeword including a plurality of data fields and corresponding parities. The codeword containing the requested data field is decoded by an error correction engine in the memory package, where the error correction engine decodes the requested data field of the codeword without decoding other ones of the data fields of the codeword. The requested data field is provided from the memory package to the controller.

In additional embodiments, a memory package includes means for error correction and one or more memory dies. The means for error correction is configured to form a user data set including a plurality of data fields into a codeword, the codeword including the user data set and corresponding parities generated by the means for error correction. The means for error correction is also configured to decode selected ones of the data fields of the codeword without decoding non-selected ones of the data fields of the codeword. The memory dies are connected to the error correction engine, and each of the memory dies includes a plurality of memory cells and means for reading and writing data connected to the plurality of memory cells and the means for error correction. The means for reading and writing data is configured to program the codeword into the plurality of memory cells and to read the codeword from the plurality of memory cells.

The means for error correction can include the various embodiments for error correction engines described above. The means can generate the parities and form code words, and decode these code words, according to the integrated interleaved (II) codes and product codes embodiments. Examples of such error correction engines and their placement within the memory system are shown, for example, by the error correction (ECC) engine elements at 34 in FIG. 1; 226 in FIGS. 4 and 11; 824 in FIG. 12; 862 in FIG. 13A; 894 in FIG. 13B; 912 in FIG. 14; 970 in FIG. 15; 1017 in FIG. 16; 2003 in FIG. 20; or some combination of these. The decoding and encoding operations can use separate hardware or share some or all of their hardware components, and be implemented as hardware, software, firmware or combinations of these.

Means for reading and writing data to and from the memory cells of an array can include the control circuitry 310, row decoder 324 and column decoder 332, and read/write circuits 328 of FIGS. 6 and 16 that read and write data to the memory cells of memory structure 326, as well as the corresponding elements 2010, 2024, 2032, and 2028 of FIG. 20.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. A memory system, comprising:
a controller; and
a memory package connected to the controller, the memory package comprising:
an error correction engine, the error correction engine configured to form a user data set including a plurality of data fields into a codeword, the codeword including the user data set and corresponding parities generated by the error correction engine, and, in response to a request for one of the data fields of the codeword, configured to decode and provide the requested data field without providing other data fields of the codeword;
one or more non-volatile memory dies, and
one or more control circuits connected to the error correction engine and the one or more memory dies, the one or more control circuits configured to program the codeword into the memory dies and read the codeword from the memory dies.

2. The memory system of claim 1, wherein the error correction engine is further configured to form the codeword as a plurality of subcodes, each of the subcodes including at least a portion of one of the data fields and corresponding parities.

3. The memory system of claim 2, the codeword further including one or more additional parities, each of the additional parities corresponding to a plurality of subcodes, and, in response to the error correction engine being unable to successfully decode the subcode for the requested data field, the error correction engine is further configured to use the additional parities to decode the subcode for the requested data field.

4. The memory system of claim 3, wherein the error correction engine is further configured to use the additional parities to decode the subcode for the requested data field.

5. The memory system of claim 3, wherein the controller is configured to use one or more of the additional parities to decode the subcode for the requested data field.

6. The memory system of claim 2, the memory package further comprising:
a compute engine connected to the error correction engine and configured to perform data manipulation operations on a decoded subcode for the requested data field, wherein the user data set is part of a database and the data manipulation operations are based on a structure of the database.

7. The memory system of claim 6, wherein the error correction engine is further configured to decode the subcode for an additional data field based on the data manipulation operations on the decoded subcode.

8. The memory system of claim 1, wherein the user data set includes a plurality of data fields logically organized into an array of rows and columns and the error correction engine is further configured to form both of the rows and the columns into codewords each having individually formed parities.

9. The memory system of claim 8, wherein in response to a request for one of the data fields, the one or more control circuits are configured to read a codeword form the one or more memory dies corresponding to the requested data field, and the error correction engine is further configured to decode the requested data field from either a row codeword or a column codeword.

10. The memory system of claim 9, wherein, in response to being unable to decode the requested data field from one of either a corresponding row codeword or a corresponding column codeword, the error correction engine is further configured to use both the corresponding row codeword and the corresponding column codeword to decode the requested data field.

11. The memory system of claim 8, the memory package further comprising:
a compute engine connected to the error correction engine and configured to perform data manipulation operations on the decoded requested data field, wherein the user data set is part of a database the data manipulation is based on a structure of the database.

12. The memory system of claim 11, wherein the error correction engine is further configured to decode an additional data field based on the data manipulation operations on the decoded requested data field.

13. The memory system of claim 1, wherein the error correction engine is formed on one or more or the memory dies.

14. The memory system of claim 1, wherein:
a first memory die of the one or more memory dies comprises a substrate and a three dimensional memory structure in which multiple memory levels are formed above the substrate.

15. A method, comprising:
receiving from a controller a request for a data field of a database at a memory package;
reading a codeword containing the requested data field from a memory die in the memory package, the codeword including a plurality of data fields and corresponding parities;
decoding the codeword containing the requested data field by an error correction engine in the memory package, where the error correction engine decodes the requested data field of the codeword without decoding other ones of the data fields of the codeword; and
providing the requested data field from the memory package to the controller.

16. The method of claim 15, wherein the codeword is formed as a plurality of subcodes, each of the subcodes including at least a portion of one of the data fields and corresponding parities, and wherein decoding the codeword containing the requested data field includes:
decoding the subcode including the requested data field and not decoding other ones of the subcodes.

17. The method of claim 16, the codeword further including one or more additional parities, each of the additional parities corresponding to a plurality of subcodes, and, wherein decoding the codeword containing the requested data field further includes:
in response to the error correction engine being unable to successfully decode the subcode for the requested data field, using the additional parities to decode the subcode for the requested data field.

18. The method of claim 15, wherein the data fields of the database are logically organized into an array of rows and columns and the data fields are written into to the memory dies in codewords in which both of the rows and the columns are formed into codewords each having individually formed parities, and wherein decoding the codeword containing the requested data field includes:
decoding the requested data field from either a row codeword or a column codeword.

19. The method of claim 18, wherein decoding the codeword containing the requested data field further includes:
in response to being unable to decode the requested data field from one of either a corresponding row codeword or a corresponding column codeword, decoding the requested data filed using both the corresponding row codeword and the corresponding column codeword.

20. A memory package, comprising:
means for error correction configured to form a user data set including a plurality of data fields into a codeword, the codeword including the user data set and corresponding parities generated by the means for error correction, and configured to decode selected ones of the data fields of the codeword without decoding non-selected ones of the data fields of the codeword; and
one or more memory dies connected to the means for error correction, each of the memory dies comprising:
a plurality of memory cells; and
means for reading and writing data connected to the plurality of memory cells and the means for error correction, configured to program the codeword into the plurality of memory cells and to read the codeword from the plurality of memory cells.
